(19) United States
(12) Patent Application Publication
(10) Pub. No.: US 2024/0107792 A1
(43) Pub. Date: Mar. 28, 2024

(54) ELECTROLUMINESCENT ELEMENT

(71) Applicants: SHARP KABUSHIKI KAISHA, Sakai City, Osaka (JP); NS Materials Inc., Chikushino-city, Fukuoka (JP)

(72) Inventors: Kazuki GOTO, Sakai City, Osaka (JP); YUSUKE SAKAKIBARA, Sakai City, Osaka (JP); Yuma YAGUCHI, Sakai City, Osaka (JP); Keisuke KITANO, Sakai City, Osaka (JP); Masaki YAMAMOTO, Sakai City, Osaka (JP); Soichiro NIKATA, Chikushino-city, Fukuoka (JP); Yoko MICHIWAKI, Chikushino-city, Fukuoka (JP); Yuko OGURA, Chikushino-city, Fukuoka (JP); Vit KALOUSEK, Chikushino-city, Fukuoka (JP); Akio MISHIMA, Chikushino-city, Fukuoka (JP)

(21) Appl. No.: 18/276,026

(22) PCT Filed: Feb. 18, 2021
(86) PCT No.: PCT/JP2021/006043

§ 371 Date: Aug. 5, 2023

(51) Int. Cl. H10K 50/115; C09K 11/02; C09K 11/58; C09K 11/62; C09K 11/88; H10K 50/15; H10K 50/16

(52) U.S. Cl. CPC H10K 50/115; C09K 11/02; C09K 11/584; C09K 11/623; C09K 11/883; H10K 50/15; H10K 50/16; H10K 2102/351

(57) ABSTRACT

A light-emitting element includes an anode electrode, a cathode electrode, and a QD layer provided between the anode electrode and the cathode electrode, the QD layer containing the QDs. The QDs are AgInₓGa₁₋ₓS_{y}Se_{1-y}-based or ZnAgInₓGa₁₋ₓS_{y}Se_{1-y}-based Cd-free QDs (0≤x<1, 0≤y≤1) and exhibit fluorescence characteristics having a fluorescent half width of 45 nm or less and a fluorescence quantum yield of 35% or more in a green wavelength region to a red wavelength region.

### TECHNICAL FIELD

The disclosure relates to an electroluminescent element containing cadmium-free quantum dots.

### BACKGROUND ART

In recent years, various techniques related to electroluminescent elements containing quantum dots have been developed.

Cd-based quantum dots containing cadmium (Cd) are commonly used as the quantum dots. The quantum dots containing Cd have advantages of having a high fluorescence quantum yield and a narrow fluorescent half width. On the other hand, Cd is internationally regulated due to its negative impact on the environment, and thus barriers for practical use are high.

Therefore, in recent years, the development of Cd-free quantum dots that are substantially free of Cd has been progressed. PTLs 1 to 5 and NPLs 1 and 2 below disclose AIS-based quantum dots containing silver (Ag), indium (In), and sulfur (S) or AIGS-based quantum dots containing Ag, In, and gallium (Ga), as Cd-free chalcopyrite-based quantum dots.

### CITATION LIST

### Patent Literature

PTL 1: JP 2017-025201 A
PTL 2: JP 2018-039971 A
PTL 3: JP 2018-044142 A
PTL 4: JP 2018-141141 A
PTL 5: WO 2018/159699 Pamphlet

### Non Patent Literature

NPL 1: NPG Asia Materials volume 10. 2018, pp713-726
NPL 2: ACS Publications 2018,10,49,41844 to 41855

### SUMMARY OF INVENTION

### Technical Problem

As described above, although research and development of Cd-free chalcopyrite-based quantum dots have been advanced, none of the quantum dots has reached performance such that the quantum dots can be an alternative to Cd-based quantum dots in terms of a fluorescent half width and a fluorescence quantum yield.

An aspect of the disclosure has been made in view of the above problem, and an object thereof is to provide an electroluminescent element containing Cd-free chalcopyrite-based quantum dots having a narrow fluorescent half width and a high fluorescence quantum yield in a range from a green wavelength region to a red wavelength region.

### Solution to Problem

In order to solve the above-described problem, an electroluminescent element according to an aspect of the disclosure includes an anode electrode, a cathode electrode, and a quantum dot light-emitting layer provided between the anode electrode and the cathode electrode, the quantum dot light-emitting layer containing quantum dots. The quantum dots are AgInₓGa₁₋ₓS_{y}Se_{1-y}-based or ZnAgInₓGa₁₋ₓS_{y}Se_{1-y}-based Cd-free quantum dots (0≤x<1, 0≤y≤1), and exhibit fluorescence characteristics having a fluorescent half width of 45 nm or less and a fluorescence quantum yield of 35% or more in a green wavelength region to a red wavelength region.

### Advantageous Effects of Invention

According to an aspect of the disclosure, an electroluminescent element containing Cd-free chalcopyrite-based quantum dots can be provided, the Cd-free chalcopyrite-based quantum dots having a narrow fluorescent half width and a high fluorescence quantum yield in a range from a green wavelength region to a red wavelength region.

### BRIEF DESCRIPTION OF DRAWINGS

FIG. 1 is a cross-sectional view schematically illustrating an overall configuration of a light-emitting element according to a first embodiment.

FIG. 2 is a schematic view illustrating an example of a QD according to the first embodiment.

FIG. 3 is a schematic view illustrating another example of the QD according to the first embodiment.

FIG. 4 is a graph showing normalized light emission luminances of Samples 1 to 4 at from 0.03 mA/cm² to 75 mA/cm² according to an example 1.

FIG. 5 is a fluorescence (photoluminescence (PL)) spectrum of AgInGaS-based QDs finally obtained in an example 2.

FIG. 6 is a fluorescence (PL) spectrum of the AgInGaS-based QDs finally obtained in an example 3.

FIG. 7 is a fluorescence (PL) spectrum of the AgInGaS-based QDs finally obtained in an example 4.

FIG. 8 is a fluorescence (PL) spectrum of the AgInGaS-based QDs finally obtained in an example 5.

FIG. 9 is a fluorescence (PL) spectrum of the AgInGaS-based QDs finally obtained in an example 6.

FIG. 10 is a fluorescence (PL) spectrum of the AgInGaS-based QDs finally obtained in an example 7.

FIG. 11 is a fluorescence (PL) spectrum of the AgInGaS-based QDs finally obtained in an example 8.

FIG. 12 is a fluorescence (PL) spectrum of the AgInGaS-based QDs finally obtained in an example 12.

FIG. 13 is a fluorescence (PL) spectrum of the AgInGaS-based QDs finally obtained in an example 13.

FIG. 14 is a fluorescence (PL) spectrum of the AgInGaS-based QDs finally obtained in an example 14.

FIG. 15 is a fluorescence (PL) spectrum of ZnAgInGaS-based QDs finally obtained in an example 15.

FIG. 16 is a fluorescence (PL) spectrum of ZnAgGaSeS-based QDs finally obtained in an example 16.

FIG. 17 is a fluorescence (PL) spectrum of the ZnAgGaSeS-based QDs finally obtained in an example 18.

FIG. 18 is a fluorescence (PL) spectrum of the ZnAgGaSeS-based QDs finally obtained in an example 19.

FIG. 19 is a fluorescence (PL) spectrum of the ZnAgInGaSeS-based QDs finally obtained in an example 20.

FIG. 20 is a fluorescence (PL) spectrum of the ZnAgGaSeS-based QDs finally obtained in an example 21.

FIG. 21 is a view illustrating an image of scanning electron micrograph of the AgInGaS-based QDs finally obtained in the example 8.

FIG. 22 is a view illustrating an analysis image using TEM-EDX of the ZnAgGaSSe-based QDs finally obtained in an example 16.

FIG. 23 is a partial schematic view of the analysis image illustrated in FIG. 22.

FIG. 24 is a cross-sectional view schematically illustrating an overall configuration of main portions of a display device according to a second embodiment.

### DESCRIPTION OF EMBODIMENTS

### First Embodiment

The electroluminescent element (hereinafter, simply denoted by “light-emitting element”) according to the present embodiment will be described as follows. Note that a description of “from A to B” for two numbers A and B is herein after intended to mean “equal to or greater than A and equal to or smaller than B”, unless otherwise specified.

### Structural Example of Light-Emitting Element

The light-emitting element according to the present embodiment includes quantum dots that emit light as a result of a combination of positive holes (holes) supplied from an anode electrode (anode) and electrons (free electrons) supplied from a cathode electrode (cathode). The quantum dots are included in a quantum dot light-emitting layer (hereinafter, simply denoted by “quantum dot layer”) provided between the anode electrode and the cathode electrode. Examples of the light-emitting element include a quantum dot light-emitting diode (QLED). Note that hereinafter, the “quantum dots” is abbreviated as “QDs”. Therefore, the quantum dot layer (quantum dot light-emitting layer) is abbreviated as a “QD layer (QD light-emitting layer)”.

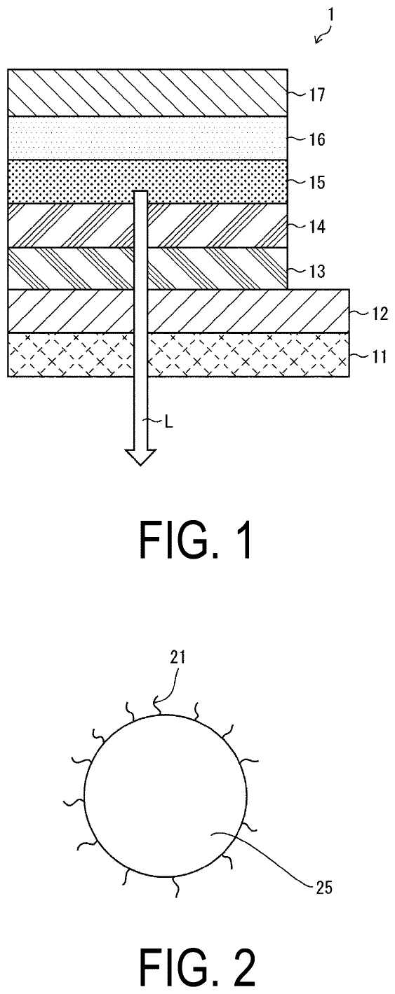

FIG. 1 is a cross-sectional view schematically illustrating an overall configuration of a light-emitting element 1 according to the present embodiment.

As illustrated in FIG. 1, the light-emitting element 1 includes an anode electrode 12 (anode, first electrode), a cathode electrode 17 (cathode, second electrode), and a function layer provided between the anode electrode 12 and the cathode electrode 17. The function layer includes at least a QD layer 15 (QD light-emitting layer) containing QDs. Note that in the present embodiment, the layers between the anode electrode 12 and the cathode electrode 17 are collectively referred to as a function layer.

The function layer may be a single layer type formed only of the QD layer 15, or may be a multi-layer type including a function layer in addition to the QD layer 15. Of the function layer, examples of function layers besides the QD layer 15 include a hole injection layer (hereinafter, denoted by “HIL”), a hole transport layer (hereinafter, denoted by “HTL”), and an electron transport layer (hereinafter, denoted by “ETL”).

Note that in the disclosure, a direction from the anode electrode 12 to the cathode electrode 17 in FIG. 1 is referred to as an upward direction, and the opposite direction thereof is referred to as a downward direction. In the disclosure, a horizontal direction is a direction (a main surface direction of each portion included in the light-emitting element 1) perpendicular to a vertical direction. The vertical direction can also be referred to as a normal direction of each portion described above.

Each layer from the anode electrode 12 to the cathode electrode 17 is generally supported by a substrate used as a support body. Accordingly, the light-emitting element 1 may be provided with a substrate as a support body.

As one example, the light-emitting element 1 illustrated in FIG. 1 has a configuration in which a substrate 11, the anode electrode 12, an HIL 13, an HTL 14, the QD layer 15, an ETL 16, and the cathode electrode 17 are layered in this order towards the upward direction of FIG. 1.

Hereinafter, each layer described above will be described in greater detail.

The substrate 11 is a support body for forming each layer from the anode electrode 12 to the cathode electrode 17, as described above.

Note that the light-emitting element 1 may be used, for example, as a light source of an electronic device such as a display device. When the light-emitting element 1 is a part of a display device, for example, a substrate of the display device is used as the substrate 11. Thus, the light-emitting element 1 may be referred to as a light-emitting element 1 including the substrate 11, or may be referred to as a light-emitting element 1 not including the substrate 11.

In this manner, the light-emitting element 1 may itself include a substrate 11, or the substrate 11 of the light-emitting element 1 may be a substrate of an electronic device such as a display device provided with the light-emitting element 1. When the light-emitting element 1 is a part of a display device, for example, an array substrate on which a plurality of thin film transistors are formed may be used as the substrate 11. In this case, the anode electrode 12, which is a first electrode provided on the substrate 11, may be electrically connected to the thin film transistors (TFTs) of the array substrate.

In the case where the light-emitting element 1 is, for example, a part of a display device in this manner, the light-emitting element 1 is provided as a light source on the substrate 11 for each pixel. Specifically, a red pixel (R pixel) is provided with, as a red light source, a light-emitting element (red light-emitting element) that emits red light. A green pixel (G pixel) is provided with, as a green light source, a light-emitting element (green light-emitting element) that emits green light. A blue pixel (B pixel) is provided with, as a blue light source, a light-emitting element (blue light-emitting element) that emits blue light. Accordingly, banks partitioning each pixel may be formed as pixel separation films such that the light-emitting element can be formed on the substrate 11 for each R pixel, G pixel, and B pixel.

In a bottom-emitting (BE) type light-emitting element having a BE structure, light emitted from the QD layer 15 is emitted downward (i.e., towards the substrate 11 side). In a top-emitting (TE) type light-emitting element having a TE structure, light emitted from the QD layer 15 is emitted upward (i.e., towards the side opposite the substrate 11). In a double-sided light-emitting element, the light emitted from the QD layer 15 is emitted downward and upward.

In a case where the light-emitting element 1 is a BE type light-emitting element or a double-sided light-emitting element, the substrate 11 is constituted of a transparent substrate having relatively high translucency such as a glass substrate, for example.

On the other hand, in a case where the light-emitting element 1 is a TE type light-emitting element, the substrate 11 may be constituted of a substrate having relatively low translucency such as a plastic substrate, or may be constituted of a light-reflective substrate having light reflectivity, for example. Note that, in the TE structure, there are few TFTs or the like that block light on the light-emitting face, so that the aperture ratio can be made high and the external quantum efficiency can be made further high.

Of the anode electrode 12 and the cathode electrode 17, the electrode serving as the light extraction surface side needs to be light-transmitting. Note that the electrode of the side opposite the light extraction surface may or may not be light-transmitting.

For example, when the light-emitting element 1 is the BE type light-emitting element, the electrode on the upper-layer side is a light-reflective electrode, and the electrode on the lower-layer side is a light-transmissive electrode. When the light-emitting element 1 is the TE type light-emitting element, the electrode on the upper-layer side is a light-transmissive electrode, and the electrode on the lower-layer side is a light-reflective electrode. Note that the light-reflective electrode may be a layered body of a layer formed of a light-transmissive material and a layer formed of a light-reflective material.

In FIG. 1, as one example, a case is illustrated in which the light-emitting element 1 is the BE type light-emitting element in which the anode electrode 12 is used as the electrode on the lower-layer side (lower-layer electrode), the cathode electrode 17 is used as the electrode on the upper-layer side (upper-layer electrode), and light L emitted from the QD layer 15 is emitted downward. Therefore, a light-transmissive electrode is used as the anode electrode 12 such that the light L emitted from the QD layer 15 can be transmitted through the anode electrode 12. Further, a light-reflective electrode is used as the cathode electrode 17 such that the light L emitted from the QD layer 15 is reflected.

The anode electrode 12 is an electrode that supplies positive holes (holes) to the QD layer 15 when a voltage is applied. The anode electrode 12 includes for example, a material having a relatively large work function. Examples of the material include tin-doped indium oxide (ITO), zinc-doped indium oxide (IZO), aluminum-doped zinc oxide (AZO), gallium-doped zinc oxide (GZO), and antimony-doped tin oxide (ATO). A single type of these materials may be used alone, or two or more types may be mixed and used, as appropriate.

The cathode electrode 17 is an electrode that supplies electrons to the QD layer 15 when a voltage is applied to the cathode electrode 17. The cathode electrode 17 includes, for example, a material having a relatively small work function. Examples of the material include aluminum (Al), silver (Ag), barium (Ba), ytterbium (Yb), calcium (Ca), lithium (Li)—Al alloys, magnesium (Mg)—Al alloys, Mg—Ag alloys, Mg-indium (In) alloys, and Al-aluminum oxide (Al₂O₃) alloys.

For example, a sputtering method, a physical vapor deposition (PVD) method such as a vacuum vapor deposition technique or the like, a spin coating method, or an ink-jet method is used for film formation of the anode electrode 12 and the cathode electrode 17.

The HIL 13 is a layer that transports positive holes supplied from the anode electrode 12 to the HTL 14. A hole transport material is used for a material of the HIL 13. The hole transport material may be an organic material or an inorganic material. When the hole transport material is the organic material, examples of the organic material include an electrically conductive polymer material. As the polymer material, for example, a composite (PEDOT:PSS) of poly(3,4-ethylenedioxythiophene) (PEDOT) and polystyrene sulfonic acid (PSS) can be used. A single type of these polymer materials may be used alone, or two or more types may be mixed and used, as appropriate. The HIL 13 preferably contains PEDOT:PSS among the above-described polymer materials. Thus, the light-emitting element 1 that has high hole mobility and can obtain favorable light-emission characteristics can be provided.

The HTL 14 is a layer that transports positive holes supplied from the HIL 13, to the QD layer 15. A hole transport material is used for a material of the HTL 14. The hole transport material may be an organic material or an inorganic material. When the hole transport material is the organic material, examples of the organic material include an electrically conductive polymer material. As the polymer material, for example, poly[(9,9-dioctylfluorenyl-2,7-diyl)-co-(4,4′-(N-(4-sec-butylphenyl) diphenylamine))] (TFB) and poly(N-vinylcarbazole) (PVK) can be used. A single type of these polymer materials may be used alone, or two or more types may be mixed and used, as appropriate. Of the above-described polymer materials, the HTL 14 preferably contains PVK. Thus, the light-emitting element 1 that has high hole mobility and can obtain favorable light-emission characteristics can be provided.

For example, PVD such as a sputtering method, a vacuum vapor deposition technique or the like, a spin coating method, or an ink-jet method is used for film formation of the HIL 13 and the HTL 14. Note that, in a case where positive holes can be sufficiently supplied to the QD layer 15 only by the HTL 14, the HIL 13 need not be provided.

The ETL 16 is a layer that transports electrons supplied from the cathode electrode 17 to the QD layer 15. An electron transport material is used for a material of the ETL 16. The electron transport material may be an organic material or an inorganic material. When the electron transport material is the organic material, the organic material preferably contains at least one type of compound selected from the group consisting of 1,3,5-tris(1-phenyl-1H-benzimidazol-2-yl)benzene (TPBi), 3-(biphenyl-4-yl)-5-(4-tert-butylphenyl)-4-phenyl-4H-1,2,4-triazole (TAZ), bathophenanthroline (Bphen), and tris(2,4,6-trimethyl-3-(pyridin-3-yl)phenyl)borane (3TPYMB), for example. A single type of these organic materials may be used alone, or two or more types may be mixed and used, as appropriate. When the ETL 16 is formed of the organic material as described above, the vacuum vapor deposition technique, the spin coating method, or the ink-jet method is preferably used for film formation of the ETL 16.

When the electron transport material is the inorganic material, the inorganic material is preferably nanoparticles composed of a metal oxide containing at least one element selected from the group consisting of zinc (Zn), magnesium (Mg), titanium (Ti), silicon (Si), tin (Sn), tungsten (W), tantalum (Ta), barium (Ba), zirconium (Zr), aluminum (Al), yttrium (Y), and hafnium (Hf). As an example of such a metal oxide, zinc oxide (ZnO), zinc magnesium oxide (ZnMgO), or the like is preferably used in terms of electron mobility. A single type of these metal oxides may be used alone, or two or more types may be mixed and used, as appropriate. Of the above-described inorganic materials, the ETL 16 preferably contains ZnMgO. Thus, the light-emitting element 1 that has high electron mobility and can obtain favorable light-emission characteristics can be provided. When the ETL 16 is formed of the inorganic material as described above, for example, PVD such as a sputtering method, a vacuum vapor deposition technique or the like, a spin coating method, or an ink-jet method is used for film formation of the ETL 16.

The QD layer 15 is a layer that contains the QDs as the light-emitting material and emits light as a result of a combination of the positive holes supplied from the anode electrode 12 and the electrons supplied from the cathode electrode 17.

The QDs are inorganic nanoparticles composed of about several thousands to several tens of thousands of atoms and having a particle size of about several nm to a dozen nm. The QDs emit fluorescence and are nano order in size, and thus the QDs are also referred to as fluorescent nanoparticles or QD phosphor particles. A composition of the QDs is derived from a semiconductor material, and thus the QDs are also referred to as semiconductor nanoparticles. The QDs have a structure having a specific crystal structure, and thus the QDs are also referred to as nanocrystals.

The QDs are composed of metal atoms that are cation species (cation raw material) having positive charges and non-metal or semimetal atoms that are anion species (anion raw material) having negative charges. The metal atoms and the semimetal atoms are bonded to each other by an ionic bond or a covalent bond. Note that the ionic bonding property of the bond depends on a combination of properties of the metal atoms and the semimetal atoms.

An emission wavelength of the QDs can be variously changed depending on the particle size of the particle, the composition of the particle, and the like. In the present embodiment, Cd-free chalcopyrite-type (ABX₂) QDs that are substantially free of cadmium (Cd) are used as the QDs. Note that, of A and B that are chalcopyrite-type cation species, an element contained in A is mainly silver (Ag), and elements contained in B are mainly indium (In) and gallium (Ga). Elements contained in X that are an anion species are sulfur (S) and selenium (Se). In the present embodiment, as the QDs, for example, a solid solution is used in which the cation raw material is based on at least Ag and Ga of Ag, Ga, In, and Zn, and the anion raw material is based on at least one of Se and S. Details are described below.

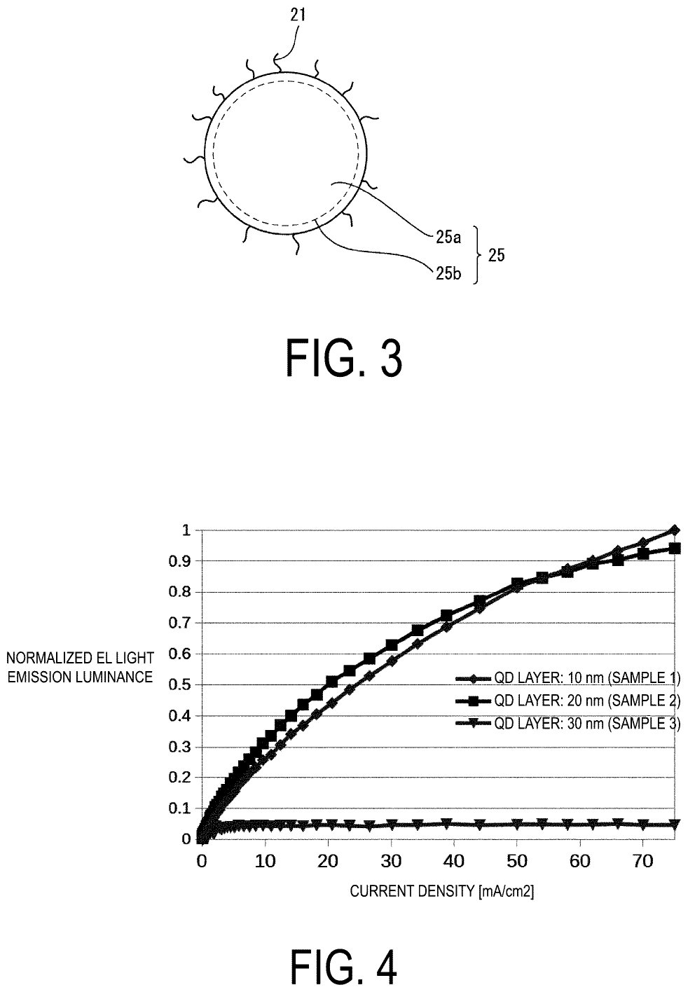

The light-emitting element 1 includes, for example, the QD 25 illustrated in FIG. 2 or the QD 25 illustrated in FIG. 3, as the QDs in the QD layer 15. FIGS. 2 and 3 are schematic views illustrating examples of the QD 25 according to the present embodiment. As described above, the QD 25 according to the present embodiment are the nanocrystals that are substantially free of Cd.

The QD 25 are chalcopyrite-based (chalcopyrite-type) Cd-free QDs made of an AgInₓGa₁₋ₓS_{y}Se_{1-y}-based or a ZnAgInₓGa₁₋ₓS_{y}Se_{1-y}-based material (0≤x<1, 0≤y≤1). In other words, the QD 25 are the AgInₓGa₁₋ₓS_{y}Se_{1-y}-based or the ZnAgInₓGa₁₋ₓS_{y}Se_{1-y}-based Cd-free QDs (0≤x<1, 0≤y≤1).

Examples of such QD 25 include QDs containing any of AgGaS, AgGaSe, AgInGaS, AgInGaSe, ZnAgGaS, ZnAgGaSe, ZnAgInGaS, and ZnAgInGaSe as a main component, or QDs made of any of AgGaS, AgGaSe, AgInGaS, AgInGaSe, ZnAgGaS, ZnAgGaSe, ZnAgInGaS, and ZnAgInGaSe.

Thus, the QD 25 are preferably nanocrystals that contain at least Ag, Ga, and at least one of S and Se, and are substantially free of Cd, and more preferably nanocrystals that are free of Cd.

Here, “the QD 25 contain at least Ag, Ga, and at least one of S and Se” means that the QD 25 contain at least Ag, Ga, and S or Ag, Ga, and Se. The QD 25 contain at least Ag, Ga, and at least one of S and Se as described above, and thus the light-emitting element 1 having a narrow fluorescent half width and a high fluorescence quantum yield can be provided.

Here, the term “nanocrystal” refers to a nanoparticle having a particle size of about several nm to several tens of nm. In the present embodiment, a large number of QD 25 can be produced with a substantially uniform particle size.

The term “substantially free of Cd” or “Cd-free” means that the QD 25 do not contain Cd in a mass ratio of 1/30 or more with respect to a total amount of the chalcopyrite-type cation species. Here, the total amount of the chalcopyrite-type cation species refers to a total amount of metal atoms represented by A and B in the chalcopyrite-type (ABX₂). Therefore, the term “substantially free of Cd” or “Cd-free” means that the QD 25 preferably do not contain Cd in the mass ratio of 1/30 or more with respect to the total amount of Ag and Ga.

Note that the QD 25 may contain Ag, Ga, and at least one of S and Se as described above, and may further contain at least one of indium (In) and zinc (Zn).

The QD 25s exhibit fluorescence regardless of whether In is contained. For example, in a case of the QD 25 that emit green light, containing In allows the QD 25 to have favorable light-emission characteristics. However, even in a case where the QDs 25 are, for example, AgGaS, light emission can be confirmed, and the QD 25s emit light even without containing In, although the fluorescent half width tends to be slightly large.

When Zn is used as a material of the chalcopyrite-based QDs such as AIS-based QDs or AIGS-based QDs represented by ABX₂, defect light emission generally occurs, and the fluorescent half width tends to be widened. This is due to a difference in a valence between Zn and the metal atoms represented by A and B (for example, Zn has a valence of 2, Ag has a valence of 1, and Ga and In have a valence of 3). However, in the present embodiment, as illustrated in examples to be described later, for example, by post-adding Zn after forming reaction initial stage particles instead of adding Zn at an initial stage of the reaction, the fluorescence quantum yield can be increased while the fluorescent half width is kept narrow even if Zn is added. That is, by using Zn for the QD 25 as described above, the light-emission characteristics of the QD 25 can be improved. The QD 25 synthesized in this way is the ZnAgInₓGa₁₋ₓS_{y}Se_{1-y}-based QDs (0≤x<1, 0≤y≤1) in which Zn is unevenly distributed mainly on surfaces of the QDs 25.

In the present embodiment, a ratio of Ag and Ga contained in the QD 25 is preferably in a range of Ag/Ga=0.1 or more and 10 or less. The ratio Ag/Ga is more preferably in a range of 0.1 or more and 5 or less, and further more preferably in a range of 0.1 or more and 3 or less.

A ratio of Zn and Ga that can be contained in the QD 25 is preferably in a range of Zn/Ga=0.1 or more and 10 or less. The ratio Zn/Ga is more preferably in a range of 0.1 or more and 5 or less, and further more preferably in a range of 0.5 or more and 5 or less. By controlling these ratios (ratio Ag/Ga and ratio Zn/Ga), the emission wavelength can be adjusted.

In the present embodiment, as will be described later, a fluorescence wavelength can be adjusted in a range, for example, from a blue wavelength region to a red wavelength region. Particularly, in the present embodiment, the fluorescence wavelength can be suitably adjusted within a range of 400 nm or more and 700 nm or less. The QDs 25 emit the fluorescence wavelength within the range of 400 nm or more and 700 nm or less, so that the light-emitting element 1 that emits light in the range from blue wavelength region to red wavelength region can be provided.

In the present embodiment, the fluorescence wavelength is preferably adjusted in a range from a green wavelength region to a red wavelength region. For example, in the present embodiment, the fluorescence wavelength can be suitably adjusted within a range of 500 nm or more and 660 nm or less. As described above, the QD 25 emit the fluorescence wavelength within the range of 500 nm or more and 660 nm or less, so that the light-emitting element 1 that emits light in the range from the green wavelength region to the red wavelength region can be provided. Note that, in the present embodiment, “fluorescent peak wavelength” and “emission peak wavelength” are abbreviated as “fluorescence wavelength ” and “emission wavelength”, respectively.

Note that, as illustrated in FIG. 3, each QD 25 may be a core-shell type QD that includes a core 25a and a shell 25b. The QD 25 illustrated in FIG. 3 has a core-shell structure including the core 25a and the shell 25b covering the surface of the core 25a. The core 25a of the QD 25 illustrated in FIG. 3 is a nanocrystal illustrated as the QD 25 in FIG. 2. Therefore, in the above description, the QD 25 can be read as the core 25a.

Therefore, in the present embodiment, the AgInₓGa₁₋ₓS_{y}Se_{1-y}-based or the ZnAgInₓGa₁₋ₓS_{y}Se_{1-y}-based Cd-free particle (0≤x<1, 0≤y≤1) is used for the core 25a.

Since the QD 25 emits fluorescence even only by the core 25a, as illustrated in FIG. 2, the QD 25 does not necessarily need to be covered with the shell 25b. It is sufficient for the QD 25 to include at least the core 25a, out of the core 25a and the shell 25b.

As described above, when the QD 25 has the core-shell structure including the core 25a of the nanocrystal including at least Ag, Ga, and at least one of S and Se and the shell 25b, a further increase in the fluorescence quantum yield can be expected while the fluorescence half width is kept narrow.

Note that, when Zn is contained inside the particle of the QD 25, the defect light emission may be dominant or only the defect light emission may be confirmed due to the difference in the valence between Zn and the metal atoms represented by A and B as described above. Therefore, as described above, Zn is desirably post-added and reacted only on the particle surfaces after forming the reaction initial stage particles, and contained only on the particle surfaces.

As described above, for example, in a case of the QD 25 that emit green light, containing In allows the QD 25 to have favorable light-emission characteristics. In the present embodiment, it is confirmed that for example, even only the core 25a can emit fluorescence by using AgGaS, AgGaSe, AgInGaS, or AgInGaSe for the core 25a. However, as described above, fluorescence is confirmed regardless of whether the QDs 25 contain In, and light emission is confirmed even when the QD 25 are free of In.

In order to synthesize the QD 25 with suppressing variation in the composition and with a composition as small as possible, the raw material of the QD 25 is preferably free of In in an initial stage reaction. In the reaction initial stage particles formed at the initial stage of the reaction, AgGaS or AgGaSe, which are free of In, has the most favorable light-emission characteristics.

Thus, the core 25a is preferably the nanocrystal that contains Ag, Ga, and at least one of S and Se, and is substantially free of Cd, and more preferably the nanocrystal that is free of Cd. Therefore, the core 25a is preferably AgGaS or AgGaSe.

Note that, similar to the core 25a, the shell 25b is free of Cd or substantially free of Cd. The material of the shell 25b is not particularly limited, and examples thereof include indium sulfide, gallium sulfide, aluminum sulfide, zinc sulfide, indium selenide, gallium selenide, aluminum selenide, and zinc selenide. At this time, as a gallium raw material (Ga raw material) used as a Ga source to be Ga contained in the QD 25 (in other words, a raw material of Ga contained in the QD 25), at least one Ga raw material selected from the group consisting of gallium chloride, gallium bromide, and gallium iodide is preferably used.

When each QD 25 includes the shell 25b, it is sufficient for the shell 25b to be provided on the surface of the core 25a. The shell 25b preferably covers the entire core 25a, but may cover at least a part of the surface of the core 25a. The QD 25 can be said to have the core-shell structure if the core 25a is found to be enveloped, in an observation of a cross-section of the QD 25. For example, from cross-section observation of 50 QD 25 adjacent to each other, a mean value (assumed dot diameter) of diameters that are areas of circles corresponding to areas of cross-sections of the QD 25 is calculated. At this time, when a difference between the assumed dot diameter and the assumed core diameter is 0. 3 nm or more, it can be said that the shell 25b envelops the core 25a (covers the entire core 25a). Note that the cross-section observation can be performed with, for example, a scanning transmission electron microscope (STEM).

The shell 25b may be in a state of being solid-solved on the surface of the core 25a. In FIG. 3, the boundary between the core 25a and the shell 25b is indicated by a dotted line, and this indicates that the boundary between the core 25a and the shell 25b may be confirmed or need not be confirmed by analysis. In the present embodiment, as will be described later, the reaction initial stage particles are formed first, and Zn is added in the final step. Thus, Zn is reacted only on the particle surface. Therefore, in the ZnAgInₓGa₁₋ₓS_{y}Se_{1-y}-based QD 25 (0≤x<1, 0≤y≤1) according to the present embodiment, even if the core-shell structure cannot be confirmed, it can be inferred from the presence of Zn that the core 25a is covered with the shell 25b.

Note that, similarly to the QD 25 illustrated in FIG. 2, in the QD 25 illustrated in FIG. 3, the fluorescence wavelength can be suitably adjusted within a range of, for example, 400 nm or more and 700 nm or less. For example, the fluorescence wavelength can be suitably adjusted within a range of 500 nm or more and 660 nm or less.

The QD 25, particularly the QD 25 that emits light in the green wavelength region, may have a structure derived from an S raw material of at least one of a thiuram-based S raw material and a disulfide-based S raw material, regardless of whether the QD 25 has the core-shell structure. The thiuram-based S raw material and the disulfide-based S raw material influence nucleation to contribute to improvement of light-emission characteristics, while they may become a ligand in the process of decomposition.

Therefore, the QD 25, in particular, the QD 25 that emits light in the green wavelength region may include, for example, at least one structure of structures represented by the following formula (1) and the following formula (2) as a structure derived from the thiuram-based S raw material and the disulfide-based S raw material.

—S—C(═S)—NR¹R² (1)

—S—R³ (2)

Note that, in the formula (1), each of R¹ and R² independently represents —(CH₂)ₙ—CH₃ group, —CH₃ group, or benzyl group, and n represents an integer from 1 to 3.

In the formula (2), R³ represents a phenyl group, a benzyl group, or a pyridyl group.

Note that, as described above, the thiuram-based S raw material and the disulfide-based S raw material are used for nucleation, while they may also become the ligand. Therefore, the QD 25 may have the above-described structure in the QD 25 itself (for example, the core 25a or the shell 25b), or may have the above-described structure in the ligands coordinated to the surface of the QD 25.

In any case, when the QD 25 has the above-described structure, the light-emitting element 1 that can obtain more favorable light-emission characteristics can be provided.

As illustrated in FIGS. 2 and 3, numerous ligands 21 are preferably coordinated (adsorbed) as the ligand on the surface of the QD 25. Each of the ligands 21 is a surface-modifying group (for example, organic ligand) that modifies the surface of the QD 25. The QD layer 15 formed by the solution method contains the spherical QD 25 and the ligands 21. By coordinating the ligands 21 on the surface of the QD 25, mutual aggregation of the QD 25 can be suppressed, and thus target optical characteristics are easily exhibited. The ligands 21 that can be used in the reaction is not particularly limited, and representative examples of the ligands 21 include amine-based (aliphatic primary amine-based), fatty acid-based, thiol-based, phosphine-based, and phosphine oxide-based ligands.

Examples of aliphatic primary amine-based ligands 21 include oleylamine (C₁₈H₃₅NH₂), stearyl (octadecyl) amine (C₁₈H₃₇NH₂), dodecyl (lauryl) amine (C₁₂H₂₅NH₂), decylamine (C₁₀H₂₁NH₂), and octylamine (C₈H₁₇NH₂).

Examples of the fatty acid-based ligands 21 include oleic acid (C₁₇H₃₃COOH), stearic acid (C₇H₃₅COOH), palmitic acid (C₁₅H₃₁COOH), myristic acid (C₁₃H₂₇COOH), lauric (dodecanoic) acid (C₁₁H₂₃COOH), decanoic acid (C₉H₁₉COOH), and octanoic acid (C₇H₁₅COOH).

Examples of thiol-based ligands 21 include octadecanethiol (C₁₈H₃₇SH), hexanedecanethiol (C₆H₃₃SH), tetradecanethiol (C₄H₂₉SH), dodecanethiol (C₂H₂₅SH), decanethiol (C₁₀H₂₁SH), and octanethiol (C₈ H₁₇SH).

Examples of the phosphine-based ligands 21 include trioctylphosphine ((C₈H₁₇)₃P), triphenylphosphine ((C₆H₅)₃P), and tributyl phosphine ((C₄H₉)₃P).

Examples of the phosphine oxide-based ligands 21 include trioctylphosphine oxide ((C₈H₁₇)₃P═O), triphenylphosphine oxide ((C₆H₅)₃P═O), and tributyl phosphine oxide ((C₄H₉)₃P═O).

Next, characteristics of the QD 25 will be described.

As described above, the QD 25 according to the present embodiment are the AgInₓGa₁₋ₓS_{y}Se_{1-y}-based or the ZnAgInₓGa₁₋ₓS_{y}Se_{1-y}-based Cd-free quantum dots (0≤x<1, 0≤y≤1). The QD 25 according to the present embodiment, regardless of whether they have the core-shell structure, exhibit fluorescence characteristics having the fluorescent half width of 45 nm or less and the fluorescence quantum yield of 35% or more in the range from the green wavelength region to the red wavelength region. Therefore, according to the present embodiment, the light-emitting element 1 containing the Cd-free chalcopyrite-based quantum dots can be provided, the Cd-free chalcopyrite-based quantum dots having the narrow fluorescent half width and the high fluorescence quantum yield in the range from the green wavelength region to the red wavelength region.

Here, the term “fluorescent half width” is a full width at half maximum, which indicates the spread of the fluorescence wavelength at half the intensity of a peak value of a fluorescence intensity in a fluorescent spectrum.

According to the present embodiment, as described above, the QD layer 15 includes the AgInₓGa₁₋ₓS_{y}Se_{1-y}-based or the ZnAgInₓGa₁₋ₓS_{y}Se_{1-y}-based QD 25 (0≤x<1, 0≤y≤1), and the QD 25 exhibit the fluorescence characteristics having the fluorescent half width of 45 nm or less and the fluorescence quantum yield of 35% or more in the range from the green wavelength region to the red wavelength region, so that the light-emitting element 1 containing the Cd-free chalcopyrite-based QD 25 can be provided, the Cd-free chalcopyrite-based QD 25 having the narrow fluorescent half width and the high fluorescence quantum yield in the range from the green wavelength region to the red wavelength region.

In the present embodiment, the fluorescent half width of the QD 25 is preferably 35 nm or less. When the fluorescent half width of the QD 25 is 35 nm or less, the chalcopyrite-based light-emitting element 1 that exhibits more favorable fluorescence characteristics can be provided. The fluorescent half width of the QD 25 is more preferably 30 nm or less, and further preferably 25 nm or less. As described above, in the present embodiment, the fluorescent half width of the QD 25 can be narrowed, and thus a high color gamut can be improved.

The fluorescence quantum yield of the QD 25 is more preferably 40% or more, more preferably 60% or more, further more preferably 70% or more, and most preferably 80% or more. In this manner, in the present embodiment, the fluorescence quantum yield of the QD 25 can be increased. Therefore, according to the present embodiment, the chalcopyrite-based light-emitting element 1 that exhibits more favorable fluorescence characteristics can be provided.

As described above, in the present embodiment, in the AgInₓGa₁₋ₓS_{y}Se_{1-y}-based or the ZnAgInₓGa₁₋ₓS_{y}Se_{1-y}-based QD 25 (0≤x<1, 0≤y≤1), the fluorescent half width can be narrowed and the fluorescence quantum yield can be increased in the range from the green wavelength region to the red wavelength region.

In the present embodiment, as described above, the fluorescence wavelength of the QD 25 can be freely controlled to a range of about 400 nm or more and 700 nm or less. Thus, in the present embodiment, the fluorescence wavelength of the QD layer 15 can be freely controlled to a range of about 400 nm or more and 700 nm or less. The QD 25 in the present embodiment are a solid-solution based on Ag, Ga, In, or Zn as the cation raw material and Se or S as the anion raw material. According to the present embodiment, by appropriately adjusting the particle size of the QD 25 and the composition of the QD 25, the fluorescence wavelength of the QD 25 and thus the emission wavelength (fluorescence wavelength) of the QD layer 15 can be controlled from blue to green to red. Therefore, the fluorescence wavelength of the QD 25 and the fluorescence wavelength of the QD layer 15 are preferably 400 nm or more and 480 nm or less, more preferably 410 nm or more and 470 nm or less, and further preferably 420 nm or more and 460 nm or less, for blue light emission. The fluorescence wavelength is preferably 500 nm or more and 560 nm or less, more preferably 510 nm or more and 550 nm or less, and further preferably 520 nm or more and 540 nm or less, for green light emission. The fluorescence wavelength is preferably 600 nm or more and 660 nm or less, more preferably 610 nm or more and 650 nm or less, and further preferably 620 nm or more and 640 nm or less, for red light emission.

As described above, according to the present embodiment, when the fluorescence wavelength of the QD 25 is within the range of 400 nm or more and 700 nm or less, the chalcopyrite-based light-emitting element 1 that emits light in the range from the blue wavelength region to the red wavelength region can be provided.

Note that, in the present embodiment, as described above, the fluorescence wavelength of the QD 25 and the fluorescence wavelength of the QD layer 15 including the QD 25 can be controlled in a range of 400 nm or more and 700 nm or less, but the QD 25 and the QD layer 15 preferably perform the green light emission or the red light emission. Thus, the chalcopyrite-based light-emitting element 1 that emits light in the range from the green wavelength region to the red wavelength region can be provided.

In general, chalcopyrite is a material having the fluorescent half width from 45 nm to 80 nm and performing defect light emission. On the other hand, the QD 25 according to the present embodiment have the narrow fluorescent half width and the high fluorescence quantum yield and thus can shorten a fluorescence lifetime much more than that of the defect light emission. From such a feature, it is presumed that the QD 25 according to the present embodiment performs band edge light emission.

In particular, according to the present embodiment, the QD 25 can be synthesized as illustrated in examples described later such that the fluorescent half width is 30 μm or less, the fluorescence quantum yield is 80% or more, and the fluorescence wavelength is in the range of 510 nm or more and 650 nm or less. According to the present embodiment, as described above, the light-emitting element 1 can be provided that has the narrow fluorescent half width and the high fluorescence quantum yield in the range from the green fluorescence wavelength (around 510 nm to 540 nm) to the red fluorescence wavelength (around 610 nm to 650 nm) and that exhibits more favorable fluorescence characteristics.

In the present embodiment, the particle size of each QD 25 is preferably within the range of 3 nm or more and 20 nm or less, and more preferably in the range of 4 nm or more and 15 nm or less. Note that, when the QD 25 has the core-shell structure, the particle size of the core 25a and the layer thickness of the shell 25b are not particularly limited.

The QD layer 15 is preferably formed such that the layer thickness is 2 nm or more and 20 nm or less. Thus, the light-emitting element 1 that has a high emission intensity and can obtain more favorable light-emission characteristics can be provided.

A technique such as spin coating, an ink-jet method, photolithography, or the like may be preferably used for film formation of the QD layer 15.

In the light-emitting element 1, a forward voltage is applied between the anode electrode 12 and the cathode electrode 17. In other words, the anode electrode 12 is set to a higher potential than the cathode electrode 17. Through this, (i) electrons can be supplied from the cathode electrode 17 to the QD layer 15, and (ii) positive holes can be supplied from the anode electrode 12 to the QD layer 15. As a result, the QD layer 15 can generate light L with a recombination of the positive holes and the electrons. The above-described application of voltage may be controlled by a TFT (not illustrated). As an example, a TFT layer including a plurality of TFTs may be formed in the substrate 11.

Note that the light-emitting element 1 may include, as a function layer, a hole blocking layer (HBL) that suppresses the transport of positive holes. The hole blocking layer is, as an example, provided between the cathode electrode 17 and the QD layer 15. By providing the hole blocking layer, the balance of the carriers (i.e., positive holes and electrons) supplied to the QD layer 15 can be adjusted.

The light-emitting element 1 may include, as a function layer, an electron blocking layer (EBL) that suppresses the transport of electrons. The electron blocking layer is, as an example, provided between the QD layer 15 and the cathode electrode 17. By providing the electron blocking layer, the balance of the carriers (i.e., positive holes and electrons) supplied to the QD layer 15 can also be adjusted.

The light-emitting element 1 may be sealed after the film formation up to the cathode electrode 17 is completed. For example, a glass or a plastic can be used as a sealing member. The sealing member desirably has, for example, a concave shape so that a layered body from the substrate 11 to the cathode electrode 17 can be sealed. For example, after a sealing adhesive (e.g., an epoxy-based adhesive) is applied between the sealing member and the substrate 11, sealing is implemented in a nitrogen (N₂) atmosphere, and thereby the light-emitting element 1 is manufactured.

The light-emitting element 1 may have a configuration in which the cathode electrode 17, the ETL 16, the QD layer 15, the HTL 14, the HIL 13, and the anode electrode 12 are layered on the substrate 11 in this order. When the light-emitting element 1 includes the ETL 16 as described above, the light-emitting element 1 may include an electron injection layer (EIL) between the ETL 16 and the cathode electrode 17.

### Manufacturing Method of Light-Emitting Element

Next, an example of a manufacturing method of the light-emitting element 1 will be described. The light-emitting element 1 is manufactured, for example, by film formation of the anode electrode 12, the HIL 13, the HTL 14, the QD layer 15, the ETL 16, and the cathode electrode 17 on the substrate 11 in this order.

Specifically, for example, the anode electrode 12 is formed on the substrate 11 by sputtering (anode electrode formation step). Next, after a solution containing the hole transport material used for a material of the HIL such as PEDOT:PSS or the like is applied to the anode electrode 12 by spin coating, the solvent is volatilized by baking to form the HIL 13 (HIL formation step). Next, after a solution containing the hole transport material used for a material of the HTL such as PVK or the like is applied to the HIL 13 by spin coating, the solvent is volatilized by baking to form the HTL 14 (HTL formation step). Next, the QD layer 15 is formed on the HTL 14 using a solution method. Specifically, after a QD dispersion (liquid composition) in which the QD 25 are dispersed is applied to the HTL 14 by spin coating, the solvent is volatilized by baking to form the QD layer 15 (QD layer formation step). Next, after a solution containing, for example, nanoparticles such as ZnMgO or the like as the electron transport material is applied to the QD layer 15 by spin coating, a solvent is volatilized by baking to form the ETL 16 (ETL formation step). Next, the cathode electrode 17 is formed on the ETL 16 by vacuum vapor deposition (cathode electrode formation step).

Note that the QD 25 contained in the QD layer 15 is manufactured (synthesized) from, for example, a silver raw material as an Ag source, a gallium raw material as a Ga source, and a sulfur raw material as an S source or a selenium raw material as an Se source (QD manufacturing step).

The Ag source indicates a raw material of Ag contained in the QD 25 (a material that becomes Ag contained in the QD 25). The Ga source indicates a raw material of Ga contained in the QD 25 (a material that becomes Ga contained in the QD 25). The S source indicates a raw material of S contained in the QD 25 (a material that becomes S contained in the QD 25). The Se source indicates a raw material of Se contained in the QD 25 (a material that becomes Se contained in the QD 25).

Note that, in the QD manufacturing step, the QD 25 may be manufactured (synthesized) by post-adding predetermined elements such as In and Zn using an indium raw material as an In source, a zinc raw material as a Zn source, and the like after forming the reaction initial stage particles from the Ag source, the Ga source, and the S source or the Se source. In the QD manufacturing step, the QD 25 may also be manufactured (synthesized) by post-adding a predetermined element such as Zn using the Zn source or the like after forming the reaction initial stage particles from the Ag source, the In source, the Ga source, and the S source or the Se source.

The In source indicates a raw material of In contained in the QD 25 (a material that becomes In contained in the QD 25). The Zn source indicates a raw material of Zn contained in the QD 25 (a material that becomes Zn contained in the QD 25).

In the QD layer formation step, the QD layer 15 containing the QD 25 synthesized in this manner is formed.

At this time, as described above, in the QD layer formation step, the QD layer 15 is formed such that the layer thickness of the QD layer 15 is 2 nm or more and 20 nm or less.

Note that, after the film formation of the cathode electrode 17, the substrate 11 and the layered body (the anode electrode 12 to the cathode electrode 17) formed on the substrate 11 may be sealed with a sealing member in an N₂ atmosphere.

### Manufacturing Method of QDs 25

Next, an example of a manufacturing method of the QD 25 (QD manufacturing step) will be described.

In the QD manufacturing step according to the present embodiment, the QDs are synthesized as the QD 25, in which the QDs are made of the AgInₓGa₁₋ₓS_{y}Se_{1-y}-base or the ZnAgInₓGa₁₋ₓS_{y}Se_{1-y}-base (0≤x<1, 0≤y≤1), and exhibit the fluorescence characteristics having the fluorescent half width of 45 nm or less and the fluorescence quantum yield of 35% or more in the range from the green wavelength region to the red wavelength region.

First, in the present embodiment, the QD 25 or the reaction initial stage particles of the QD 25 are heated and synthesized by one pot from a silver raw material (Ag raw material) as the Ag source, an indium raw material (In raw material) as the In source, and a sulfur raw material (S raw material) as the S source or a selenium raw material (Se raw material) as the Se source.

At this time, a reaction temperature is set in a range of 100° C. or more and 320° C. or less, and for example, AgGaS, AgGaSe, AgInGaS, or AgInGaSe is synthesized as the reaction initial stage particles. Note that the reaction temperature is preferably 280° C. or less, which is a further lower temperature.

As the Ag raw material, an organic silver compound or an inorganic silver compound is used. As the Ag raw material, for example, but not particularly limited to, a halide such as silver acetate (CH₃C(═O)OAg, another name: Ag(OAc)), silver nitrate (AgNO₃), silver chloride (AgCl), silver bromide (AgBr), and silver iodide (AgI) and a carbamate such as silver diethyldithiocarbamate (Ag(SC(═S)N(C₂H₅)₂)), silver dimethyldithiocarbamate (Ag(SC(═S)N(CH₃)₂)), and the like can be used. A single type of these Ag raw materials may be used alone, or two or more types may be mixed and used, as appropriate.

The Ag raw material may be directly added to the reaction solution, or may be dissolved in an organic solvent in advance and used as an Ag raw material solution having a certain concentration.

As the In raw material, an organic indium compound or an inorganic indium compound is used. As the In raw material, for example, but not particularly limited to, a halide such as indium acetate (In(CH₃C(═O)O)₃, another name: In(OAc)₃), indium nitrate (InNO₃), indium acetylacetonate (In(CH₃C(═O)CH═C(═O)CH₃)₃, another name: In(acac)₃), indium chloride (InCl₃), silver bromide (InBr₃), and indium iodide (InI₃), and a carbamate such as indium diethyldithiocarbamate (In[(SC(═S)N(C₂H₅)₂)₂]₃), indium dimethyldithiocarbamate(In[SC(═S)N(CH₃)₂]₃), and the like can be used. A single type of these In raw materials may be used alone, or two or more types may be mixed and used, as appropriate.

As the Ga raw material, an organic indium compound or an inorganic indium compound is used. As the Ga raw material, for example, but not particularly limited to, a halide such as gallium acetate (Ga(OAc)₃), gallium nitrate (GaNO₃), gallium acetylacetonate (Ga(CH₃C(═O)CH═C(═O)CH₃)₃, another name: Ga(acac)₃), gallium chloride (GaCl₃), gallium bromide (GaBr₃), and gallium iodide (Ga₂I₆), and a carbamate such as gallium diethyldithiocarbamate (Ga[(SC(═S)N(C₂H₅)₂)₂]₃), and the like can be used. A single type of these Ga raw materials may be used alone, or two or more types may be mixed and used, as appropriate. Of these Ga raw materials, gallium acetylacetonate (Ga(acac)₃) and gallium chloride (GaCl₃) are particularly easily available and can provide good characteristics. Therefore, as the Ga raw material, at least one of gallium acetylacetonate and gallium chloride is preferably used.

The In raw material or Ga raw material may be directly added to the reaction solution, or may be dissolved in an organic solvent in advance and used as an In raw material solution or a Ga raw material solution having a certain concentration.

As the S raw material, an organic sulfur compound such as thiol or sulfur (S) can be used. Examples of the organic sulfur compound include, but are not particularly limited to, octadecanethiol (C₈H₃₇SH), hexanedecanethiol (C₆H₃₃SH), tetradecanethiol (C₁₄H₂₉SH), dodecanethiol (C₂H₂₅SH), decanethiol (C₁₀H₂₁SH), and octanethiol (C₈H₁₇SH). A single type of these S raw materials may be used alone, or two or more types may be mixed and used, as appropriate.

In particular, when AgGaS or AgInGaS is synthesized as the QD 25 or the reaction initial stage particles of the QD 25, S raw material species greatly contribute to the fluorescence characteristics. In the present embodiment, as the S raw material (S source), at least one S raw material selected from the group consisting of a solution (S-ODE (S-ODE raw material)) in which thiurams (thiuram-based S raw material), disulfide (disulfide-based S raw material), sulfur (S) is dissolved in octadecene (ODE), and a solution (S-OLAm/DDT) in which S is dissolved in oleylamine and dodecanethiol is preferably used. Thus, the light-emitting element 1 that can obtain more favorable light-emission characteristics can be provided. Of these, S-ODE can provide the fluorescent half width of 40 nm or less and the fluorescence quantum yield of 40% or more.

However, further favorable characteristics can be obtained by using disulfide as the S raw material. Examples of the disulfide (disulfide-based S raw material) include diphenyl disulfide, dibenzyl disulfide, isopropylxanthogen disulfide, and 4,4′-dithiodimorpholine.

By using thiurams (thiuram-based S raw materials) as the S raw material, further favorable fluorescence characteristics can be obtained. Examples of the thiurams (thiuram-based S raw materials) include thiuram disulfide, dipentamethylenethiuram tetrasulfide, tetraethylthiuram disulfide, and tetramethylthiuram disulfide.

Note that, in addition to the above-described S raw materials, the S raw material may be, for example, a raw material having a structure (—S—)ₙ in which a plurality of sulfur atoms are connected, or a raw material having a structure such as a structure (N—S—) in which nitrogen is bonded to sulfur or a structure (C—S—) in which carbon is bonded to sulfur.

As the Se raw material, an organic selenium compound (organic chalcogen compound) or selenium (Se) can be used. As the organic selenium compound (organic chalcogen compound), for example, but not particularly limited to, trioctylphosphine selenide ((C₈H₁₇)₃P═Se) obtained by dissolving Se in trioctylphosphine, tributylphosphine selenide ((C₄H₉)₃P═Se) obtained by dissolving Se in tributylphosphine, a solution obtained by dissolving, at a high temperature, Se in a high-boiling solvent which is a long-chain hydrocarbon such as octadecene, and a solution (Se-OLAm/DDT) obtained by dissolving Se in mixtures of oleylamine and dodecanethiol can be used. A single type of these Se raw materials may be used alone, or two or more types may be mixed and used, as appropriate.

The S raw material or Se raw material may be also directly added to the reaction solution, or may be dissolved in an organic solvent in advance and used as an S raw material solution or a Se raw material solution having a certain concentration.

When AgGaSe or AgInGaSe is synthesized as the QD 25 or the reaction initial stage particles of the QD 25, Se raw material species greatly contribute to the fluorescence characteristics. In particular, a solution (Se-OLAm/DDT) obtained by dissolving Se in a mixture of oleylamine and dodecanethiol exhibits favorable light-emission characteristics. In a normal chalcopyrite-based QDs, two kinds of light emission of a PL spectrum considered to be band edge light emission and a PL spectrum considered to be defect light emission can be confirmed at the initial stage of light emission, and a ratio of the light emission intensity thereof is such that band edge light emission/defect light emission is 10 or less in most cases. Thereafter, as the reaction further proceeds, the intensity of the defect light emission gradually decreases, and the intensity of the band edge light emission also increases accordingly in many cases. However, when Se-DDT/OLAm is used as the Se source as in the present embodiment, a single peak is confirmed from the initial stage of light emission, the band edge light emission/defect light emission is 10 or more, and a peak considered to be the defect light emission is hardly confirmed. The fluorescence lifetime until becoming 1/e is 20 ns or less, and only a peak which is not the defect light emission can be confirmed at the initial stage of light emission. Therefore, by using the Se-OLAm/DDT as the Se source, the light-emitting element 1 that can obtain further favorable light-emission characteristics can be provided.

As the Zn raw material, an organic zinc compound or an inorganic zinc compound is used. The organic zinc compound and the inorganic zinc compound are raw materials that are stable even in air and easy to handle. As the Zn raw material, for example, but not particularly limited to, a fatty acid salt such as zinc acetate (Zn(OAc)₂) which is an acetate, zinc nitrate (Zn(NO₃)₂), zinc stearate (Zn(OC(═O)C₁₇H₃₅)₂), zinc oleate (Zn(OC(═O)C₁₇H₃₃)₂), zinc palmitate (Zn(OC(═O)C₁₅H₃₁)₂), zinc myristate (Zn(OC(═O)C₁₃H₂₇)₂), zinc dodecanoate (Zn(OC(═O)C₁₁H₂₃)₂), zinc acetylacetonate (Zn(CH₃C(═O)CH═C(═O)CH₃)₂, another name: Zn(acac)₂), and the like, a halide such as zinc chloride (ZnCl₂), zinc bromide (ZnBr₂), and zinc iodide (ZnI₂), and zinc carbamate such as zinc diethyldithiocarbamate (Zn(SC(═S)N(C₂H₅)₂)₂), zinc dimethyldithiocarbamate (Zn(SC(═S)N(CH₃)₂)₂), and zinc dibutyldithiocarbamate (Zn(SC(═S)N(C₄H₉)₂)₂ can be used. A single type of these Zn raw materials may be used alone, or two or more types may be mixed and used, as appropriate.

The Zn raw material may also be directly added to the reaction solution, or may be dissolved in an organic solvent in advance and used as a Zn raw material solution having a certain concentration.

In the present embodiment, the QD 25 can be obtained by one pot without isolating and purifying the precursor.

In the present embodiment, the synthesized QD 25 exhibit fluorescence characteristics without the implementation of various treatments such as cleaning, isolation and purification, a covering treatment, ligand exchange, and the like.

Note that, as described in FIG. 3, the fluorescence quantum yield can be further increased by covering the core 25a made of the nanocrystal with the shell 25b.

The fluorescence quantum yield can be further increased by purifying the QD 25 with specific solvent after forming the core-shell structure. Examples of the specific solvent include trioctylphosphine (TOP).

The manufacturing method of the QD 25 according to the present embodiment preferably includes a centrifugal separation step. The QD 25 having more excellent light-emission characteristics can be obtained by performing the centrifugal separation on the reaction solution obtained by the synthesis.

In particular, the QD 25 having more excellent light-emission characteristics can be obtained by mixing the reaction solution obtained by the synthesis with polar solvents such as toluene, methanol, ethanol, and acetone as solvents (for example, poor solvents), and performing centrifugal separation to remove aggregates.

In the manufacturing method of the QD 25 according to the present embodiment, as described above, the QD 25 may be synthesized by post-adding the predetermined element after forming the reaction initial stage particles. In this case, the QD 25 are preferably free of In at the initial stage of the reaction. As described above, specifically, in the reaction initial stage particles formed at the initial stage of the reaction, AgGaS or AgGaSe, which are free of In, has the most favorable light-emission characteristics.

In general, In is contained from the initial stage of the reaction, and the In/Ga ratio is adjusted or the like, however, an object of the present embodiment is to suppress variation in the composition of the QD 25 and to synthesize the QD 25 with a composition as small as possible. Therefore, as described above, the raw material of the QD 25 is preferably free of In in the initial stage reaction. In other words, the QD 25 formed at the initial stage of the reaction are preferably free of In. According to the present embodiment, the QD 25 are free of In at the initial stage of the reaction as described above, and thus it is presumed that the light-emission characteristics having the narrow fluorescent half width can be obtained.

Note that the QD 25 that emit green light preferably contain In finally, and In can be contained in the QD 25 during the reaction process. Note that, it is not essential that the QD 25 that emit green light contain In. As described above, for example, it can be confirmed that light is emitted even when the QD 25 are free of In although the fluorescent half width is slightly widened.

In the present embodiment, in including Zn in the QD 25, Zn is preferably added with paying attention to the following points. First, Zn is preferably added in the final step instead of adding Zn during the initial stage reaction. This is because, as described above, when Zn is contained inside the particles of the QD 25, the defect light emission may be dominant or only the defect light emission may be confirmed. Therefore, Zn is preferably added in the final step so that Zn is reacted only on the particle surfaces. Second, Zn is preferably added at a low temperature. Here, the low temperature means a temperature approximately from 150° C. to 200° C. In a case where the temperature at the time of adding Zn is high, Zn reacts even to the inside the particles of the QD 25, so that the defective light emission is likely to occur. Therefore, in order to limit the reaction between the QD 25 and Zn to the particle surfaces of the QD 25, Zn is preferably reacted only on the particle surfaces of the QD 25 at the low temperature.

In the present embodiment, in synthesizing AgGaSe, Se-OLAm/DDT is preferably used as the Se raw material as described above. As a result, the defective light emission can be effectively suppressed.

In synthesizing AgGaS, the thiuram-based S raw material, particularly tetraethylthiuram disulfide is preferable as the S raw material rather than a generally used raw material which is derived from dissolving sulfur powder, because favorable light-emission characteristics can be obtained.

In the centrifugal separation, large particles and small particles are separated from each other. In the present embodiment, in the centrifugal separation step, the centrifugal separation is performed by adding a solvent such as toluene or ethanol. Thus, even if the particle sizes of the QD 25 are uniform, by controlling a ratio of solvents such as toluene and ethanol, a degree of aggregation of the QD 25 can be changed depending on a difference in the type, amount, and the like of the ligands 21 coordinated to the surfaces of the QD 25. At this time, the ratio can be controlled within a range of QDs 25:toluene:ethanol=1:from 0.5 to 2:from 0.5 to 2. Note that methanol may be used in place of ethanol. As a result, QD 25 having high fluorescence quantum yield and QD 25 having low fluorescence quantum yield can be separated from each other. Thereafter, by adding trioctylphosphine (TOP) to the separated QD 25, the fluorescence quantum yield can be further improved.

As described above, according to the manufacturing method of the quantum dots of the present embodiment, the Cd-free quantum dots that have the narrow fluorescent half width and the high fluorescence quantum yield can be safely synthesized by a mass-producible method.

### EXAMPLES

Next, effects of the QD 25 and the light-emitting element 1 according to the present embodiment will be described through examples and comparative examples. Note that the QD 25 and the light-emitting element 1 according to the present embodiment are not limited to the following examples.

Note that raw materials and measuring instruments used in the following examples and comparative examples are as follows.

### Solvent

Octadecene (ODE) available from Aldrich Co., Ltd. was used as ODE. Oleylamine (OLAm) available from Kao Corporation was used as OLAm. Dodecanethiol (DDT) available from Kao Corporation was used as DDT. “Lunac O-V” available from Kao Corporation was used as oleic acid (OLAc). Trioctylphosphine (TOP) available from Hokko Chemical Industry Co., Ltd. was used as TOP. Myristic acid (MA) available from Kishida Chemical Co., Ltd. was used as MA. Toluene available from DAISHIN CHEMICAL CO., LTD was used as toluene. Ethanol available from DAISHIN CHEMICAL CO., LTD was used as ethanol.

Note that, of the above solvents, OLAc, OLAm, DDT, and TOP also function as ligands.

### Ag Raw Material

Silver acetate (Ag(OAc)) available from Aldrich Co., Ltd. was used as Ag(OAc). Ag(OAc)-OLAm solution (concentration 0.2 M) was prepared by dissolving silver acetate (Ag(OAc)) in oleylamine (OLAm).

### In Raw Material

Indium acetate (In(OAc)₃) available from Shinko Chemical Industry Co., Ltd was used as In(OAc)₃. Synthetic raw material (indium thiocarbamate) synthesized by the inventor was used as indium diethyldithiocarbamate. In(OAc)₃-OLAm/OLAc (In(OAc)₃-OLAm/OLAc solution) (concentration 0.2 M) was prepared by dissolving indium acetate (In(OAc)₃) in oleylamine (OLAm) and oleic acid (OLAc). In(acac)₃-OLAm/OLAc (In(OAc)₃-OLAm/OLAc solution) (concentration 0.02 M) was prepared by dissolving indium acetylacetonate (In(acac)₃) in oleylamine (OLAm) and oleic acid (OLAc).

### Ga Raw Material

Gallium chloride (GaCl₃) available from Shinko Chemical Industry Co., Ltd was used as GaCl₃. Gallium acetylacetonate (Ga(acac)₃) available from Tokyo Chemical Industry Co., Ltd. was used as Ga(acac)₃. GaCl₃/OLAc-ODE (GaCl₃/OLAc-ODE solution) (molar ratio Ga:OLAc=1:1.5, concentration 0.1 M) was prepared by dissolving gallium chloride (GaCl₃) and oleic acid (OLAc) in octadecene (ODE) such that the molar ratio was Ga:OLAc=1:1.5. GaCl₃/OLAc-ODE (GaCl₃/OLAc-ODE solution) (molar ratio Ga:OLAc=1:3, concentration 0.1 M) was prepared by dissolving gallium chloride (GaCl₃) and oleic acid (OLAc) in octadecene (ODE) such that the molar ratio was Ga:OLAc=1:3. GaCl₃/MA-ODE (GaCl₃/MA-ODE solution) (molar ratio Ga:MA=1:3, concentration 0.1 M) was prepared by dissolving gallium chloride (GaCl₃) and myristic acid (MA) in octadecene (ODE) such that the molar ratio was Ga:MA=1:3. GaCl₃/OLAc-OLAm (GaCl₃/OLAc-OLAm solution) (molar ratio Ga:OLAc=1:3, concentration 0.1 M) was prepared by dissolving gallium chloride (GaCl₃) and oleic acid (OLAc) in oleylamine (OLAm) such that the molar ratio was Ga:OLAc=1:3. GaCl₃/OLAc-OLAm (GaCl₃/OLAc-OLAm solution) (molar ratio Ga:OLAc=1:1.5, concentration 0.1 M) was prepared by dissolving gallium chloride (GaCl₃) and oleic acid (OLAc) in oleylamine (OLAm) such that the molar ratio was Ga:OLAc=1:1.5.

### S Raw Material

Sulfur (S) available from Kishida Chemical Co., Ltd. was used as S. Tetraethylthiuram disulfide (TETDS) available from Sanshin Chemical Industrial Co., Ltd was used as TETDS. Dipentamethylenethiuram tetrasulfide (DPTT) available from Sanshin Chemical Industrial Co., Ltd was used as DPTT. Isopropylxanthogen disulfide (IPXDS) available from Sanshin Chemical Industrial Co., Ltd was used as IPXDS. Tetramethylthiuram disulfide (TMTDS) available from Sanshin Chemical Industrial Co., Ltd was used as TMTDS. TETDS-OLAm (TETDS-OLAm solution) (concentration 0.4 M) was prepared by dissolving tetraethylthiuram disulfide (TETDS) in oleylamine (OLAm). S-ODE (S-ODE solution) (concentration 0.2 M) was prepared by dissolving sulfur (S) in octadecene (ODE). DPTT-OLAm (DPTT-OLAm solution) (concentration 0.4 M) was prepared by dissolving dipentamethylenethiuram tetrasulfide (DPTT) in oleylamine (OLAm). DTDM-OLAm (DTDM-OLAm solution) (concentration 0.4 M) was prepared by dissolving 4,4′-dithiodimorpholine (DTDM) in oleylamine (OLAm). IPXDS-OLAm (IPXDS-OLAm solution) (concentration 0.4 M) was prepared by dissolving isopropylxanthogen disulfide in oleylamine (OLAm). TMTDS-OLAm (TMTDS-OLAm solution) (concentration 0.4 M) was prepared by dissolving tetramethylthiuram disulfide (TMTDS) in oleylamine (OLAm). S-TOP (S-TOP solution) (concentration 0.2 M) was prepared by dissolving sulfur (S) in trioctylphosphine (TOP). S-OLAm/DDT (S-OLAm/DDT solution) (concentration 0.8 M) was prepared by dissolving sulfur (S) in oleylamine (OLAm) and dodecanethiol (DDT).

### Se Raw Material

Se-OLAm/DDT (Se-OLAm/DDT solution) (concentration 0.7 M) was prepared by dissolving selenium (Se) in oleylamine (OLAm) and dodecanethiol (DDT).

### Zn Raw Material

Zinc acetate (Zn(OAc)₂) available from Kishida Chemical Co., Ltd. was used as Zn(OAc)₂. Zn(OAc)₂-OLAc/TOP (Zn(OAc)₂-OLAc/TOP solution) (concentration 0.8 M) was prepared by dissolving zinc acetate (Zn(OAc)₂) in oleic acid (OLAc) and trioctylphosphine (TOP). Zn(OAc)₂-OLAc/OLAm (Zn(OAc)₂-OLAm solution) (concentration 0.4 M) was prepared by dissolving zinc acetate (Zn(OAc)₂) in oleic acid (OLAc) and oleylamine (OLAm).

### Measuring Instrument

“F-2700” available from JASCO Corporation was used as the fluorescence spectrometer. “QE-1100” available from Otsuka Electronics Co., Ltd. was used as the quantum yield measuring device. The scanning electron microscope (SEM) function of “SU9000” available from Hitachi, Ltd. was used as the SEM. A light-emitting diode(LED) measuring device available from Spectra Co-op (two-dimensional CCD small high sensitivity spectrometer: “Solid Lambda CCD” available from Carl Zeiss AG) was used as the LED measuring device. The scanning transmission electron microscope (STEM) function of “SU9000” available from Hitachi, Ltd. was used as the STEM. “JEM-ARM200CF” available from JEOL Ltd. was used as the transmission electron microscope (TEM). The energy dispersive X-ray (EDX) analysis function of “JED 2300T” available from JEOL Ltd. was used as EDX analyzer.

### Example 1

The above-described Ag(OAc)-OLAm (concentration 0.2 M) 0.5 mL, gallium acetylacetonate (Ga(acac)₃) 91.8 mg, oleylamine (OLAm) 9.5 mL, and dodecanethiol (DDT) 0.5 mL were charged in a 100 mL reaction vessel. In an inert gas (N₂) atmosphere, the raw materials in the reaction vessel were then heated at 120° C. for 5 minutes while being stirred to be dissolved, and a solution was thereby obtained.

Next, the TETDS-OLAm (concentration 0.4 M) 0.5 mL was added to the solution in the reaction vessel from above the solution. Thereafter, the temperature of the solution in the reaction vessel was raised from 120° C. to 200° C., and the solution was stirred for 20 minutes in total. Thereafter, the obtained reaction solution (AgGaS dispersion (1A) containing AgGaS-based particles as the reaction initial stage particles) was cooled to ambient temperature.

The In(OAc)₃-OLAm/OLAc (concentration 0.2 M) 0.375 mL and the S-ODE 1.225 mL were added to the obtained reaction solution (AgGaS dispersion (1A)), and the mixture was heated while being stirred again at 270° C. for 10 minutes. Thereafter, the obtained reaction solution (AgInGaS dispersion (1B) containing AgInGaS-based QD 25) was cooled to ambient temperature. Thereafter, cleaning separation was performed on the QD 25 using toluene and ethanol. Note that the cleaning separation indicates a step of separation by controlling the degree of aggregation due to a difference in the coordination state of the ligands 21 coordinated to the QD 25 by a ratio of a solvent (nonpolar solvent (apolar solvent)) such as toluene and a poor solvent (polar solvent) such as ethanol.

Thereafter, the QD 25 were redispersed with oleylamine (OLAm) to obtain an AgInGaS dispersion (1C) containing the QD 25. Next, the AgInGaS dispersion (1C) was heated to 270° C. again and stirred.

Thereafter, a mixed solution 4.5 mL obtained by mixing the GaCl₃/OLAc-ODE (molar ratio Ga:OLAc=1:1.5, concentration 0.1 M) 3 mL and the S-ODE (concentration 0.2 M) 1.5 mL was dropped to the reaction solution (AgInGaS dispersion (1C)) being heated at 270° C. while being stirred from above the reaction solution over 50 minutes. After completion of the dropping of the mixed solution, the reaction solution to which the mixed solution had been dropped was heated while being stirred for 70 minutes. Thereafter, the obtained reaction solution (AgInGaS dispersion (1D) containing the AgInGaS-based QD 25) was cooled to ambient temperature.

Thereafter, trioctylphosphine (TOP) 3 mL was added to the reaction solution (AgInGaS dispersion (1D)), and the mixture was heated at 200° C. for 10 minutes. Thereafter, the obtained reaction solution (AgInGaS dispersion containing the QDs 25 (1E)) was cooled to ambient temperature. Thereafter, the cleaning separation was performed on the QD 25 using toluene and ethanol.

Thereafter, the QD 25 were redispersed with toluene to obtain a QD dispersion (1F) containing the QD 25. Then, the fluorescence wavelength and the fluorescent half width of the QD 25 in the QD dispersion (1F) were measured by the fluorescence spectrometer described above. The fluorescence quantum yield of the QD 25 in the QD dispersion (1F) was measured by the quantum yield measuring device. The measurement results indicated optical characteristics including the fluorescence wavelength of 532 nm, the fluorescent half width of 38 nm, and the fluorescence quantum yield of 45%. The particle size of the QD 25 was measured by the scanning transmission electron microscope (STEM) and found to be 8.1 nm. The particle size was calculated from an average value of observed samples in particle observation using the STEM.

Note that the composition of the reaction initial stage particles, the post-added element, the fluorescence wavelength, the fluorescent half width, the fluorescence quantum yield, and the S raw material as the S source in the present example are collectively shown in Table 1 below. Note that, in Table 1, “composition of the reaction initial stage particles”, “fluorescence wavelength”, “fluorescent half width”, and “fluorescence quantum yield” are denoted by “initial stage particle composition”, “wavelength”, “half width”, and “PLQY”, respectively.

As described above, according to the present example, it was found that the QDs 25 that emit green light were obtained. According to the present example, it was found that the fluorescent half width can be made 45 nm or less, preferably 40 nm or less. It was found that the fluorescence quantum yield can be made 35% or more, preferably 40% or more. Therefore, according to the present example, it is found that, by using the QDs 25 as the QDs, the light-emitting element 1 that contains the Cd-free chalcopyrite-based QDs having the narrow fluorescent half width and the high fluorescence quantum yield and that emits green light can be provided.

Next, using the QD dispersion (1F) described above, three types of light-emitting elements 1 having the following layered structures were manufactured as Samples 1 to 3.
Sample 1: ITO (30 nm)/PEDOT:PSS (40 nm)/PVK (30 nm)/QD layer (10 nm)/ZnMgO (60 nm)/Al (100 nm)
Sample 2: ITO (30 nm)/PEDOT:PSS (40 nm)/PVK (30 nm)/QD layer (20 nm)/ZnMgO (60 nm)/Al (100 nm)
Sample 3: ITO (30 nm)/PEDOT:PSS (40 nm)/PVK (30 nm)/QD layer (30 nm)/ZnMgO (60 nm)/Al (100 nm)

Specifically, in each sample, the anode electrode 12 having a thickness of 30 nm was formed on the substrate 11, which was a glass substrate, by sputtering ITO. Next, a solution containing PEDOT:PSS was applied onto the anode electrode 12 by spin coating, and then the solvent was volatilized by baking. Thus, in each sample, the HIL 13 (PEDOT:PSS layer) having a layer thickness 40 nm was formed. Next, a solution containing PVK was applied on the HIL 13 by spin coating, and then the solvent was volatilized by baking. Thus, in each sample, the HTL 14 (PVK layer) having a layer thickness 30 nm was formed. Next, the QD dispersion (1F) was applied onto the HTL 14 by spin coating, and then the solvent was volatilized by baking. As a result, the QD layer 15 (AgInGaS-based QD layer) having the layer thickness 10 nm in the Sample 1, the layer thickness 20 nm in the Sample 2, and the layer thickness 30 nm in the Sample 3 was formed. Next, a solution containing ZnMgO nanoparticles was applied onto the QD layer 15 by spin coating and then the solvent was volatilized by baking. Thus, in each sample, the ETL16 (ZnMgO nanoparticle layer) having a layer thickness 60 nm was formed. Next, in each sample, the cathode electrode 17 having a thickness 100 nm was formed on the ETL 16 by vacuum vapor depositing Al. Next, the substrate 11 and the layered body formed on the substrate 11 in each sample were sealed with a sealing member in an N₂ atmosphere.

Next, a current (more precisely, a current density) of 0.03 mA/cm² to 75 mA/cm² was applied to each sample. Then, by applying the current, electroluminescence (EL) light emission luminance of the light L emitted from each sample was measured by the LED measuring device (spectrometer).

FIG. 4 is a graph showing normalized light emission luminance obtained by normalizing the EL light emission luminance from 0.03 mA/cm² to 75 mA/cm² of each of the Samples 1 to 4, with the EL light emission luminance at 75 mA/cm² of the Sample 1 as 1.

From the results shown in FIG. 4, it is found that, when the layer thickness of the QD layer 15 is 20 nm or less, further favorable light-emission characteristics can be obtained than when the layer thickness of the QD layer 15 is 30 nm.

According to the present example, as described above, it is found that, the HIL13 and the HTL14 are provided in this order from the anode electrode 12 side between the anode electrode 12 and the QD layer 15, the ETL16 is provided between the cathode electrode 17 and the QD layer 15, the HIL13 contains PEDOT:PSS which is a composite of poly (3, 4-ethylenedioxythiophene) and polystyrene sulfonic acid, the HTL14 contains PVK, and the ETL 16 contains ZnMgO, and thus the light-emitting element 1 that can obtain favorable light-emission characteristics can be provided.

### Example 2

The above-described Ag(OAc)-OLAm (concentration 0.2 M) 1.5 mL, gallium acetylacetonate (Ga(acac)₃) 165 mg, oleylamine (OLAm) 28.5 mL, and dodecanethiol (DDT) 1.5 mL were charged in a 300 mL reaction vessel. In an inert gas (N₂) atmosphere, the raw materials in the reaction vessel were then heated at 120° C. for 5 minutes while being stirred to be dissolved, and a solution was thereby obtained.

Next, the TETDS-OLAm (concentration 0.4 M) 1.5 mL was added to the solution in the reaction vessel from above the solution. Thereafter, the temperature of the solution in the reaction vessel was raised from 120° C. to 200° C., and the solution was stirred for 20 minutes in total. Thereafter, the obtained reaction solution (AgGaS dispersion (2A) containing AgGaS-based particles as the reaction initial stage particles) was cooled to ambient temperature.

Indium diethyldithiocarbamate (In[SC(═S)N(C₂H₅)₂]₃) 125.7 mg was added, as carbamate, to the obtained reaction solution (AgGaS dispersion (2A)), and the mixture was heated while being stirred again at 270° C. for 10 minutes.

Thereafter, a mixed solution 13.5 mL obtained by mixing the GaCl₃/MA-ODE (molar ratio Ga:MA=1:3, concentration 0.1 M) 9 mL and the S-ODE (concentration 0.2 M) 4.5 mL was dropped to the reaction solution being heated while being stirred at 270° C. from above the reaction solution over 50 minutes. After completion of the dropping of the mixed solution, the reaction solution to which the mixed solution had been dropped was heated while being stirred for 70 minutes. Thereafter, the obtained reaction solution (AgInGaS dispersion (2B) containing AgInGaS-based QD 25) was cooled to ambient temperature.

The fluorescence wavelength and the fluorescent half width of the QD 25 in the obtained reaction solution (AgInGaS dispersion (2B)) were measured by the fluorescence spectrometer described above. The fluorescence quantum yield of the QD 25 in the reaction solution (AgInGaS dispersion (2B)) was measured by the quantum yield measuring device described above. The measurement results indicated optical characteristics including the fluorescence wavelength of 539 nm, the fluorescent half width of 35 nm, and the fluorescence quantum yield of 49%.

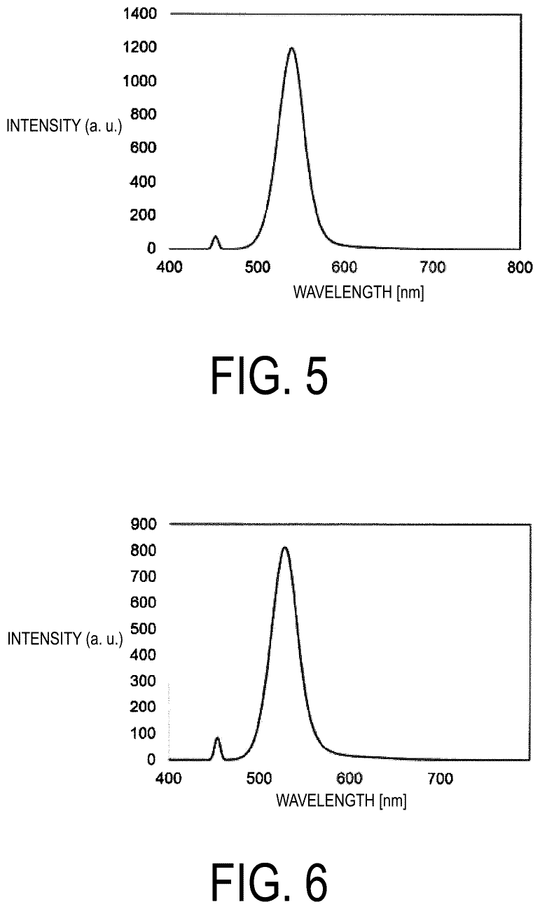

Thereafter, the QD 25 were purified by repeating twice an operation of performing cleaning separation of the QD 25 using toluene and ethanol and then redispersing the QD 25 with trioctylphosphine (TOP). The fluorescence wavelength and the fluorescent half width of the QD 25 in the obtained QD dispersion (2C) containing the QD 25 were measured by the fluorescence spectrometer described above. The fluorescence quantum yield of the QD 25 in the QD dispersion (2C) was measured by the quantum yield measuring device described above. As shown in FIG. 5, the measurement results indicated optical characteristics including the fluorescence wavelength of 539 nm, the fluorescent half width of 35.4 nm, and the quantum yield of 75%.

Therefore, also in the present example, the QD 25 that emit green light and have the fluorescent half width of 45 nm or less and the fluorescence quantum yield of 35% or more could be obtained. Therefore, also in the present example, it is found that, by using the QD 25 as the QDs, the light-emitting element 1 that contains the Cd-free chalcopyrite-based QDs having the narrow fluorescent half width and the high fluorescence quantum yield and that emits green light can be provided.

Note that the composition of the reaction initial stage particles, the post-added element, the fluorescence wavelength, the fluorescent half width, the fluorescence quantum yield, and the S raw material as the S source in the present example are also collectively shown in Table 1 below.

### Example 3

The above-described Ag(OAc)-OLAm (concentration 0.2 M) 0.5 mL, gallium acetylacetonate (Ga(acac)₃) 55 mg, oleylamine (OLAm) 9.5 mL, and dodecanethiol (DDT) 0.5 mL were charged in a 100 mL reaction vessel. In an inert gas (N₂) atmosphere, the raw materials in the reaction vessel were then heated at 120° C. for 5 minutes while being stirred to be dissolved, and a solution was thereby obtained.

Next, the DPTT-OLAm (concentration 0.4 M) 0.5 mL was added to the solution in the reaction vessel from above the solution. Thereafter, the temperature of the solution in the reaction vessel was raised from 120° C. to 200° C., and the solution was stirred for 20 minutes in total. Thereafter, the obtained reaction solution (AgGaS dispersion (3A) containing AgGaS-based particles as the reaction initial stage particles) was cooled to ambient temperature.

Indium diethyldithiocarbamate (In[SC(═S)N(C₂H₅)₂]₃) 41.9 mg was added, as carbamate, to the obtained reaction solution (AgGaS dispersion (3A)), and the mixture was heated while being stirred again at 270° C. for 10 minutes.

Thereafter, a mixed solution 4.5 mL obtained by mixing the GaCl₃/MA-ODE (molar ratio Ga:MA=1:3, concentration 0.1 M) 3 mL and the S-ODE (concentration 0.2 M) 1.5 mL was dropped to the reaction solution being heated while being stirred at 270° C. from above the reaction solution over 50 minutes. After completion of the dropping of the mixed solution, the reaction solution to which the mixed solution had been dropped was heated while being stirred for 70 minutes. Thereafter, the obtained reaction solution (AgInGaS dispersion (3B) containing AgInGaS-based QD 25) was cooled to ambient temperature.

The fluorescence wavelength and the fluorescent half width of the QD 25 in the obtained reaction solution (AgInGaS dispersion (3B)) were measured by the fluorescence spectrometer described above. The fluorescence quantum yield of the QD 25 in the reaction solution (AgInGaS dispersion (3B)) was measured by the quantum yield measuring device described above. The measurement results indicated optical characteristics including the fluorescence wavelength of 526 nm, the fluorescent half width of 35.5 nm, and the fluorescence quantum yield of 34%.

Thereafter, the QD 25 were purified by repeating twice the operation of performing cleaning separation of the QD 25 using toluene and ethanol and then redispersing the QD 25 with trioctylphosphine (TOP). The fluorescence wavelength and the fluorescent half width of the QD 25 in the obtained QD dispersion (3C) containing the QD 25 were measured by the fluorescence spectrometer. The fluorescence quantum yield of the QD 25 in the QD dispersion (3C) was measured by the quantum yield measuring device described above. As shown in FIG. 6, the measurement results indicated optical characteristics including the fluorescence wavelength of 526.5 nm, the fluorescent half width of 34.8 nm, and the quantum yield of 54%.

Therefore, also in the present example, the QD 25 that emit green light and have the fluorescent half width of 45 nm or less and the fluorescence quantum yield of 35% or more could be obtained. Therefore, also in the present example, it is found that, by using the QD 25 as the QDs, the light-emitting element 1 that contains the Cd-free chalcopyrite-based QDs having the narrow fluorescent half width and the high fluorescence quantum yield and that emits green light can be provided.

Note that the composition of the reaction initial stage particles, the post-added element, the fluorescence wavelength, the fluorescent half width, the fluorescence quantum yield, and the S raw material as the S source in the present example are also collectively shown in Table 1 below.

### Example 4

The above-described Ag(OAc)-OLAm (concentration 0.2 M) 0.5 mL, gallium acetylacetonate (Ga(acac)₃) 55 mg, oleylamine (OLAm) 9.5 mL, and dodecanethiol (DDT) 0.5 mL were charged in a 100 mL reaction vessel. In an inert gas (N₂) atmosphere, the raw materials in the reaction vessel were then heated at 120° C. for 5 minutes while being stirred to be dissolved, and a solution was thereby obtained.

Next, the DTDM-OLAm (concentration 0.4 M) 0.5 mL was added to the solution in the reaction vessel from above the solution. Thereafter, the temperature of the solution in the reaction vessel was raised from 120° C. to 200° C., and the solution was stirred for 20 minutes in total. Thereafter, the obtained reaction solution (AgGaS dispersion (4A) containing AgGaS-based particles as the reaction initial stage particles) was cooled to ambient temperature.

Indium diethyldithiocarbamate (In[SC(═S)N(C₂H₅)₂]₃) 41.9 mg was added, as carbamate, to the obtained reaction solution (AgGaS dispersion (4A)), and the mixture was heated while being stirred again at 270° C. for 10 minutes.

Thereafter, a mixed solution 4.5 mL obtained by mixing the GaCl₃/MA-ODE (molar ratio Ga:MA=1:3, concentration 0.1 M) 3 mL and the S-ODE (concentration 0.2 M) 1.5 mL was dropped to the reaction solution being heated while being stirred at 270° C. from above the reaction solution over 50 minutes. After completion of the dropping of the mixed solution, the reaction solution to which the mixed solution had been dropped was heated while being stirred for 70 minutes. Thereafter, the obtained reaction solution (AgInGaS dispersion (4B) containing AgInGaS-based QD 25) was cooled to ambient temperature.

The fluorescence wavelength and the fluorescent half width of the QD 25 in the obtained reaction solution (AgInGaS dispersion (4B)) were measured by the fluorescence spectrometer described above. The fluorescence quantum yield of the QD 25 in the reaction solution (AgInGaS dispersion (4B)) was measured by the quantum yield measuring device described above. The measurement results indicated optical characteristics including the fluorescence wavelength of 526 nm, the fluorescent half width of 37.5 nm, and the quantum yield of 41%.

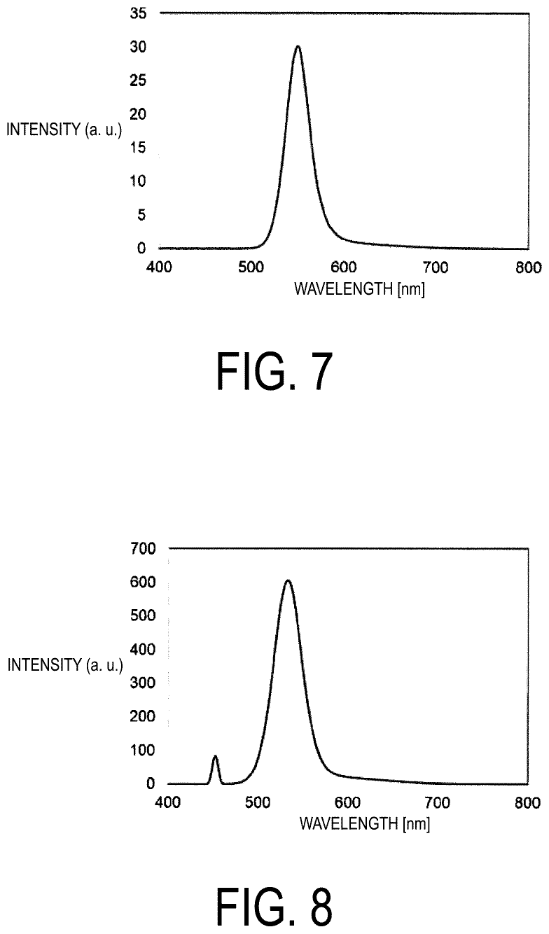

Thereafter, the QD 25 were purified by repeating twice the operation of performing cleaning separation of the QD 25 using toluene and ethanol and then redispersing the QD 25 with trioctylphosphine (TOP). The fluorescence wavelength and the fluorescent half width of the QD 25 in the obtained QD dispersion (4C) containing the QD 25 were measured by the fluorescence spectrometer. The fluorescence quantum yield of the QD 25 in the QD dispersion (4C) was measured by the quantum yield measuring device described above. As shown in FIG. 7, the measurement results indicated optical characteristics including the fluorescence wavelength of 527.5 nm, the fluorescent half width of 36.9 nm, and the quantum yield of 56%.

Therefore, also in the present example, the QD 25 that emit green light and have the fluorescent half width of 45 nm or less and the fluorescence quantum yield of 35% or more could be obtained. Therefore, also in the present example, it is found that, by using the QD 25 as the QDs, the light-emitting element 1 that contains the Cd-free chalcopyrite-based QDs having the narrow fluorescent half width and the high fluorescence quantum yield and that emits green light can be provided.

Note that the composition of the reaction initial stage particles, the post-added element, the fluorescence wavelength, the fluorescent half width, the fluorescence quantum yield, and the S raw material as the S source in the present example are also collectively shown in Table 1 below.

### Example 5

The above-described Ag(OAc)-OLAm (concentration 0.2 M) 0.5 mL, gallium acetylacetonate (Ga(acac)₃) 55 mg, oleylamine (OLAm) 9.5 mL, and dodecanethiol (DDT) 0.5 mL were charged in a 100 mL reaction vessel. In an inert gas (N₂) atmosphere, the raw materials in the reaction vessel were then heated at 120° C. for 5 minutes while being stirred to be dissolved, and a solution was thereby obtained.

Next, the IPXDS-OLAm (concentration 0.4 M) 0.5 mL was added to the solution in the reaction vessel from above the solution. Thereafter, the temperature of the solution in the reaction vessel was raised from 120° C. to 200° C., and the solution was stirred for 20 minutes in total. Thereafter, the obtained reaction solution (AgGaS dispersion (5A) containing AgGaS-based particles as the reaction initial stage particles) was cooled to ambient temperature.

Indium diethyldithiocarbamate (In[SC(═S)N(C₂H₅)₂]₃) 41.9 mg was added, as carbamate, to the obtained reaction solution (AgGaS dispersion (5A)), and the mixture was heated while being stirred again at 270° C. for 10 minutes.

Thereafter, a mixed solution 4.5 mL obtained by mixing the GaCl₃/MA-ODE (molar ratio Ga:MA=1:3, concentration 0.1 M) 3 mL and the S-ODE (concentration 0.2 M) 1.5 mL was dropped to the reaction solution being heated while being stirred at 270° C. from above the reaction solution over 50 minutes. After completion of the dropping of the mixed solution, the reaction solution to which the mixed solution had been dropped was heated while being stirred for 70 minutes. Thereafter, the obtained reaction solution (AgInGaS dispersion (5B) containing AgInGaS-based QD 25) was cooled to ambient temperature.

The fluorescence wavelength and the fluorescent half width of the QD 25 in the obtained reaction solution (AgInGaS dispersion (5B)) were measured by the fluorescence spectrometer described above. The fluorescence quantum yield of the QD 25 in the reaction solution (AgInGaS dispersion (5B)) was measured by the quantum yield measuring device described above. The measurement results indicated optical characteristics including the fluorescence wavelength of 530 nm, the fluorescent half width of 37 nm, and the quantum yield of 40%.

Thereafter, the QD 25 were purified by repeating twice the operation of performing cleaning separation of the QD 25 using toluene and ethanol and then redispersing the QD 25 with trioctylphosphine (TOP). The fluorescence wavelength and the fluorescent half width of the QD 25 in the obtained QD dispersion (5C) containing the QD 25 were measured by the fluorescence spectrometer. The fluorescence quantum yield of the QD 25 in the QD dispersion (5C) was measured by the quantum yield measuring device described above. As shown in FIG. 8, the measurement results indicated optical characteristics including the fluorescence wavelength of 532 nm, the fluorescent half width of 36.9 nm, and the quantum yield of 65%.

Therefore, also in the present example, the QD 25 that emit green light and have the fluorescent half width of 45 nm or less and the fluorescence quantum yield of 35% or more could be obtained. Therefore, also in the present example, it is found that, by using the QD 25 as the QDs, the light-emitting element 1 that contains the Cd-free chalcopyrite-based QDs having the narrow fluorescent half width and the high fluorescence quantum yield and that emits green light can be provided.

Note that the composition of the reaction initial stage particles, the post-added element, the fluorescence wavelength, the fluorescent half width, the fluorescence quantum yield, and the S raw material as the S source in the present example are also collectively shown in Table 1 below.

### Example 6

The above-described Ag(OAc)-OLAm (concentration 0.2 M) 0.5 mL, gallium acetylacetonate (Ga(acac)₃) 55 mg, oleylamine (OLAm) 9.5 mL, and dodecanethiol (DDT) 0.5 mL were charged in a 100 mL reaction vessel. In an inert gas (N₂) atmosphere, the raw materials in the reaction vessel were then heated at 120° C. for 5 minutes while being stirred to be dissolved, and a solution was thereby obtained.

Next, the TMTDS-OLAm (concentration 0.4 M) 0.5 mL was added to the solution in the reaction vessel from above the solution. Thereafter, the temperature of the solution in the reaction vessel was raised from 120° C. to 200° C., and the solution was stirred for 20 minutes in total. Thereafter, the obtained reaction solution (AgGaS dispersion (6A) containing AgGaS-based particles as the reaction initial stage particles) was cooled to ambient temperature.

Indium diethyldithiocarbamate (In[SC(═S)N(C₂H₅)₂]₃) 41.9 mg was added, as carbamate, to the obtained reaction solution (AgGaS dispersion (6A)), and the mixture was heated while being stirred again at 270° C. for 10 minutes.

Thereafter, a mixed solution 4.5 mL obtained by mixing the GaCl₃/MA-ODE (molar ratio Ga:MA=1:3, concentration 0.1 M) 3 mL and the S-ODE (concentration 0.2 M) 1.5 mL was dropped to the reaction solution being heated while being stirred at 270° C. from above the reaction solution over 50 minutes. After completion of the dropping of the mixed solution, the reaction solution to which the mixed solution had been dropped was heated while being stirred for 70 minutes. Thereafter, the obtained reaction solution (AgInGaS dispersion (6B) containing AgInGaS-based QD 25) was cooled to ambient temperature.

The fluorescence wavelength and the fluorescent half width of the QD 25 in the obtained reaction solution (AgInGaS dispersion (6B)) were measured by the fluorescence spectrometer described above. The fluorescence quantum yield of the QD 25 in the reaction solution (AgInGaS dispersion (6B)) was measured by the quantum yield measuring device described above. The measurement results indicated optical characteristics including the fluorescence wavelength of 542 nm, the fluorescent half width of 36.5 nm, and the quantum yield of 54%.

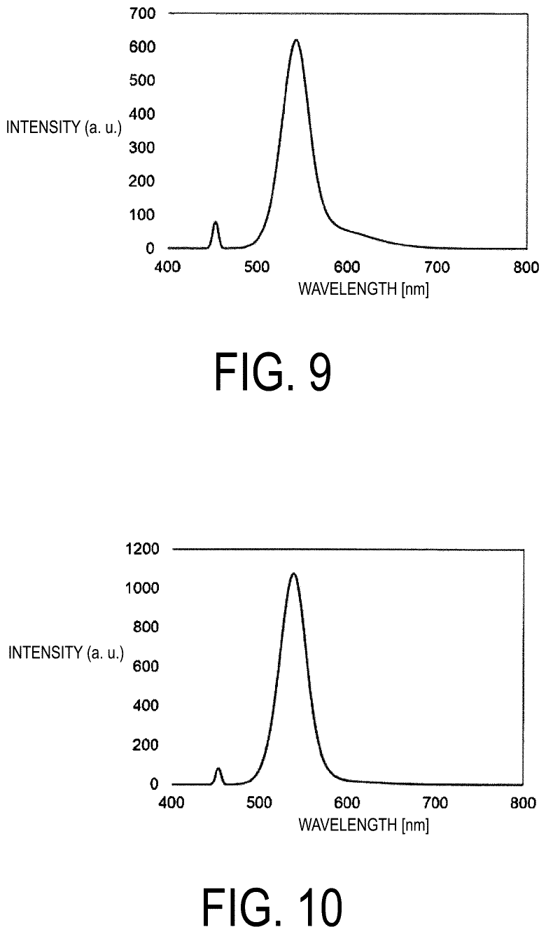

Thereafter, the QD 25 were purified by repeating twice the operation of performing cleaning separation of the QD 25 using toluene and ethanol and then redispersing the QD 25 with trioctylphosphine (TOP). The fluorescence wavelength and the fluorescent half width of the QD 25 in the obtained QD dispersion (6C) containing the QD 25 were measured by the fluorescence spectrometer. The fluorescence quantum yield of the QD 25 in the QD dispersion (6C) was measured by the quantum yield measuring device described above. As shown in FIG. 9, the measurement results indicated optical characteristics including the fluorescence wavelength of 542 nm, the fluorescent half width of 36.5 nm, and the quantum yield of 71%.

Therefore, also in the present example, the QD 25 that emit green light and have the fluorescent half width of 45 nm or less and the fluorescence quantum yield of 35% or more could be obtained. Therefore, also in the present example, it is found that, by using the QD 25 as the QDs, the light-emitting element 1 that contains the Cd-free chalcopyrite-based QDs having the narrow fluorescent half width and the high fluorescence quantum yield and that emits green light can be provided.

Note that the composition of the reaction initial stage particles, the post-added element, the fluorescence wavelength, the fluorescent half width, the fluorescence quantum yield, and the S raw material as the S source in the present example are also collectively shown in Table 1 below.

### Example 7

The above-described Ag(OAc)-OLAm (concentration 0.2 M) 0.5 mL, gallium acetylacetonate (Ga(acac)₃) 55 mg, oleylamine (OLAm) 9.5 mL, and dodecanethiol (DDT) 0.5 mL were charged in a 100 mL reaction vessel. In an inert gas (N₂) atmosphere, the raw materials in the reaction vessel were then heated at 120° C. for 5 minutes while being stirred to be dissolved, and a solution was thereby obtained.

Next, the TETDS-OLAm (concentration 0.4 M) 0.5 mL was added to the solution in the reaction vessel from above the solution. Thereafter, the temperature of the solution in the reaction vessel was raised from 120° C. to 200° C., and the solution was stirred for 20 minutes in total. Thereafter, the obtained reaction solution (AgGaS dispersion (7A) containing AgGaS-based particles as the reaction initial stage particles) was cooled to ambient temperature.

Indium diethyldithiocarbamate (In[SC(═S)N(C₂H₅)₂]₃) 41.9 mg was added, as carbamate, to the obtained reaction solution (AgGaS dispersion (7A)), and the mixture was heated while being stirred again at 270° C. for 10 minutes.

Thereafter, a mixed solution 4.5 mL obtained by mixing the GaCl₃/OLAc-ODE (molar ratio Ga:OLAc=1:3, concentration 0.1 M) 3 mL and the S-ODE (concentration 0.2 M) 1.5 mL was dropped to the reaction solution being heated while being stirred at 270° C. from above the reaction solution over 50 minutes. After completion of the dropping of the mixed solution, the reaction solution to which the mixed solution had been dropped was heated while being stirred for 70 minutes. Thereafter, the obtained reaction solution (AgInGaS dispersion (7B) containing AgInGaS-based QD 25) was cooled to ambient temperature.

The fluorescence wavelength and the fluorescent half width of the QD 25 in the obtained reaction solution (AgInGaS dispersion (7B)) were measured by the fluorescence spectrometer described above. The fluorescence quantum yield of the QD 25 in the reaction solution (AgInGaS dispersion (7B)) was measured by the quantum yield measuring device described above. The measurement results indicated optical characteristics including the fluorescence wavelength of 546 nm, the fluorescent half width of 29.3 nm, and the quantum yield of 39%.

Thereafter, the QD 25 were purified by repeating twice the operation of performing cleaning separation of the QD 25 using toluene and ethanol and then redispersing the QD 25 with trioctylphosphine (TOP). The fluorescence wavelength and the fluorescent half width of the QD 25 in the obtained QD dispersion (7C) containing the QD 25 were measured by the fluorescence spectrometer. The fluorescence quantum yield of the QD 25 in the QD dispersion (7C) was measured by the quantum yield measuring device described above. As shown in FIG. 10, the measurement results indicated optical characteristics including the fluorescence wavelength of 548.5 nm, the fluorescent half width of 30.5 nm, and the quantum yield of 59%.

Therefore, also in the present example, the QD 25 that emit green light and have the fluorescent half width of 45 nm or less and the fluorescence quantum yield of 35% or more could be obtained. Therefore, also in the present example, it is found that, by using the QD 25 as the QDs, the light-emitting element 1 that contains the Cd-free chalcopyrite-based QDs having the narrow fluorescent half width and the high fluorescence quantum yield and that emits green light can be provided.

Note that the composition of the reaction initial stage particles, the post-added element, the fluorescence wavelength, the fluorescent half width, the fluorescence quantum yield, and the S raw material as the S source in the present example are also collectively shown in Table 1 below.

### Example 8

The above-described Ag(OAc)-OLAm (concentration 0.2 M) 0.5 mL, gallium acetylacetonate (Ga(acac)₃) 55 mg, oleylamine (OLAm) 9.5 mL, and dodecanethiol (DDT) 0.5 mL were charged in a 100 mL reaction vessel. In an inert gas (N₂) atmosphere, the raw materials in the reaction vessel were then heated at 120° C. for 5 minutes while being stirred to be dissolved, and a solution was thereby obtained.

Next, the TMTDS-OLAm (concentration 0.4 M) 0.5 mL was added to the solution in the reaction vessel from above the solution. Thereafter, the temperature of the solution in the reaction vessel was raised from 120° C. to 200° C., and the solution was stirred for 20 minutes in total. Thereafter, the obtained reaction solution (AgGaS dispersion (8A) containing AgGaS-based particles as the reaction initial stage particles) was cooled to ambient temperature.

Indium acetate (In(OAc)₃) 21.8 mg and S-ODE (concentration 0.2 M) 0.75 mL were added to the obtained reaction solution (AgGaS dispersion (8A)), and the mixture was heated while being stirred again at 270° C. for 10 minutes.

Thereafter, a mixed solution 4.5 mL obtained by mixing the GaCl₃/MA-ODE (molar ratio Ga:MA=1:3, concentration 0.1 M) 3 mL and the S-ODE (concentration 0.2 M) 1.5 mL was dropped to the reaction solution being heated while being stirred at 270° C. from above the reaction solution over 50 minutes. After completion of the dropping of the mixed solution, the reaction solution to which the mixed solution had been dropped was heated while being stirred for 70 minutes. Thereafter, the obtained reaction solution (AgInGaS dispersion (8B) containing AgInGaS-based QD 25) was cooled to ambient temperature.

The fluorescence wavelength and the fluorescent half width of the QD 25 in the obtained reaction solution (AgInGaS dispersion (8B)) were measured by the fluorescence spectrometer described above. The fluorescence quantum yield of the QD 25 in the reaction solution (AgInGaS dispersion (8B)) was measured by the quantum yield measuring device described above. The measurement results indicated optical characteristics including the fluorescence wavelength of 546 nm, the fluorescent half width of 36.5 nm, and the quantum yield of 55%.

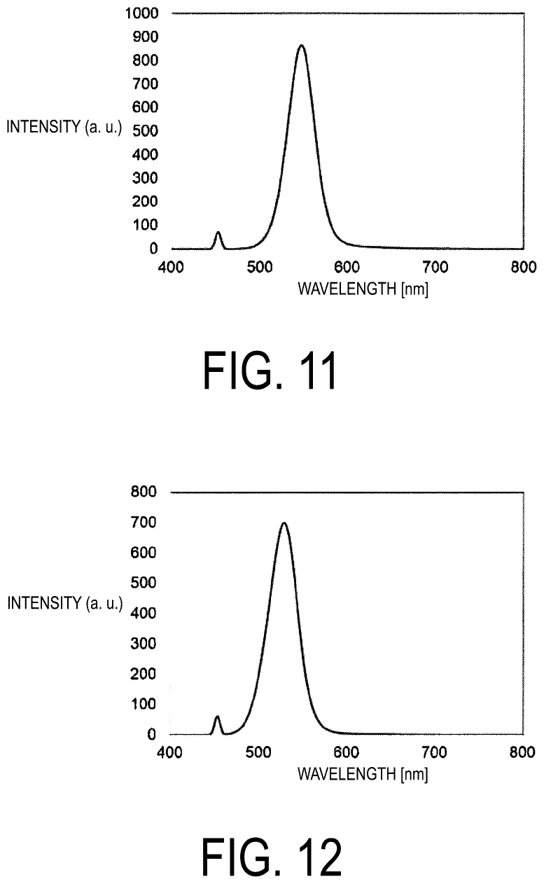

Thereafter, the QD 25 were purified by repeating twice the operation of performing cleaning separation of the QD 25 using toluene and ethanol and then redispersing the QD 25 with trioctylphosphine (TOP). The fluorescence wavelength and the fluorescent half width of the QD 25 in the obtained QD dispersion (8C) containing the QD 25 were measured by the fluorescence spectrometer. The fluorescence quantum yield of the QD 25 in the QD dispersion (8C) was measured by the quantum yield measuring device described above. As shown in FIG. 11, the measurement results indicated optical characteristics including the fluorescence wavelength of 546.5 nm, the fluorescent half width of 36.2 nm, and the quantum yield of 81%.

Therefore, also in the present example, the QD 25 that emit green light and have the fluorescent half width of 45 nm or less and the fluorescence quantum yield of 35% or more could be obtained. Therefore, also in the present example, it is found that, by using the QD 25 as the QDs, the light-emitting element 1 that contains the Cd-free chalcopyrite-based QDs having the narrow fluorescent half width and the high fluorescence quantum yield and that emits green light can be provided.

Note that the composition of the reaction initial stage particles, the post-added element, the fluorescence wavelength, the fluorescent half width, the fluorescence quantum yield, and the S raw material as the S source in the present example are also collectively shown in Table 1 below.

### Example 9

The above-described Ag(OAc)-OLAm (concentration 0.2 M) 0.5 mL, gallium acetylacetonate (Ga(acac)₃) 55 mg, oleylamine (OLAm) 9.5 mL, and dodecanethiol (DDT) 0.5 mL were charged in a 100 mL reaction vessel. In an inert gas (N₂) atmosphere, the raw materials in the reaction vessel were then heated at 120° C. for 5 minutes while being stirred to be dissolved, and a solution was thereby obtained.

Next, the S-ODE (concentration 0.2 M) 1 mL was added to the solution in the reaction vessel from above the solution. Thereafter, the temperature of the solution in the reaction vessel was raised from 120° C. to 200° C., and the solution was stirred for 20 minutes in total. Thereafter, the obtained reaction solution (AgGaS dispersion (9A) containing AgGaS-based particles as the reaction initial stage particles) was cooled to ambient temperature.

Indium acetate (In(OAc)₃) 21.8 mg and S-ODE (concentration 0.2 M) 2.25 mL were added to the obtained reaction solution (AgGaS dispersion (9A)), and the mixture was heated while being stirred again at 270° C. for 10 minutes.

Thereafter, a mixed solution 4.5 mL obtained by mixing the GaCl₃/MA-ODE (molar ratio Ga:MA=1:3, concentration 0.1 M) 3 mL and the S-ODE (concentration 0.2 M) 1.5 mL was dropped to the reaction solution being heated while being stirred at 270° C. from above the reaction solution over 50 minutes. After completion of the dropping of the mixed solution, the reaction solution to which the mixed solution had been dropped was heated while being stirred for 70 minutes. Thereafter, the obtained reaction solution (AgInGaS dispersion (9B) containing AgInGaS-based QD 25) was cooled to ambient temperature.

The fluorescence wavelength and the fluorescent half width of the QD 25 in the obtained reaction solution (AgInGaS dispersion (9B)) were measured by the fluorescence spectrometer described above. The fluorescence quantum yield of the QD 25 in the reaction solution (AgInGaS dispersion (9B)) was measured by the quantum yield measuring device described above. The measurement results indicated optical characteristics including the fluorescence wavelength of 523 nm, the fluorescent half width of 36.5 nm, and the quantum yield of 25%.

Thereafter, the QD 25 were purified by repeating twice the operation of performing cleaning separation of the QD 25 using toluene and ethanol and then redispersing the QD 25 with trioctylphosphine (TOP). The fluorescence wavelength and the fluorescent half width of the QD 25 in the obtained QD dispersion (9C) containing the QD 25 were measured by the fluorescence spectrometer. The fluorescence quantum yield of the QD 25 in the QD dispersion (9C) was measured by the quantum yield measuring device described above. The measurement results indicated optical characteristics including the fluorescence wavelength of 522 nm, the fluorescent half width of 38 nm, and the quantum yield of 46%.

Therefore, also in the present example, the QD 25 that emit green light and have the fluorescent half width of 45 nm or less and the fluorescence quantum yield of 35% or more could be obtained. Therefore, also in the present example, it is found that, by using the QD 25 as the QDs, the light-emitting element 1 that contains the Cd-free chalcopyrite-based QDs having the narrow fluorescent half width and the high fluorescence quantum yield and that emits green light can be provided.

Note that the composition of the reaction initial stage particles, the post-added element, the fluorescence wavelength, the fluorescent half width, the fluorescence quantum yield, and the S raw material as the S source in the present example are collectively shown in Table 2 below. Note that, also in Table 2, “composition of the reaction initial stage particles”, “fluorescence wavelength”, “fluorescent half width”, and “fluorescence quantum yield” are denoted by “initial stage particle composition”, “wavelength”, “half width”, and “PLQY”, respectively.

### Example 10

The above-described Ag(OAc)-OLAm (concentration 0.2 M) 0.5 mL, gallium acetylacetonate (Ga(acac)₃) 55 mg, oleylamine (OLAm) 9.5 mL, and dodecanethiol (DDT) 0.5 mL were charged in a 100 mL reaction vessel. In an inert gas (N₂) atmosphere, the raw materials in the reaction vessel were then heated at 120° C. for 5 minutes while being stirred to be dissolved, and a solution was thereby obtained.

Next, the S-ODE (concentration 0.2 M) 1 mL was added to the solution in the reaction vessel from above the solution. Thereafter, the temperature of the solution in the reaction vessel was raised from 120° C. to 200° C., and the solution was stirred for 20 minutes in total. Thereafter, the obtained reaction solution (AgGaS dispersion (10A) containing AgGaS-based particles as the reaction initial stage particles) was cooled to ambient temperature.

Indium diethyldithiocarbamate (In[SC(═S)N(C₂H₅)₂]₃) 41.9 mg was added, as carbamate, to the obtained reaction solution (AgGaS dispersion (10A)), and the mixture was heated while being stirred again at 270° C. for 10 minutes.

Thereafter, a mixed solution 4.5 mL obtained by mixing the GaCl₃/MA-ODE (molar ratio Ga:MA=1:3, concentration 0.1 M) 3 mL and the S-ODE (concentration 0.2 M) 1.5 mL was dropped to the reaction solution being heated while being stirred at 270° C. from above the reaction solution over 50 minutes. After completion of the dropping of the mixed solution, the reaction solution to which the mixed solution had been dropped was heated while being stirred for 70 minutes. Thereafter, the obtained reaction solution (AgInGaS dispersion (10B) containing AgInGaS-based QD 25) was cooled to ambient temperature.

The fluorescence wavelength and the fluorescent half width of the QD 25 in the obtained reaction solution (AgInGaS dispersion (10B)) were measured by the fluorescence spectrometer described above. The fluorescence quantum yield of the QDs 25 in the reaction solution (AgInGaS dispersion (10B)) was measured by the quantum yield measuring device described above. The measurement results indicated optical characteristics including the fluorescence wavelength of 534 nm, the fluorescent half width of 36 nm, and the quantum yield of 33%.

Thereafter, the QD 25 were purified by repeating twice the operation of performing cleaning separation of the QD 25 using toluene and ethanol and then redispersing the QD 25 with trioctylphosphine (TOP). The fluorescence wavelength and the fluorescent half width of the QD 25 in the obtained QD dispersion (10C) containing the QD 25 were measured by the fluorescence spectrometer. The fluorescence quantum yield of the QD 25 in the QD dispersion (10C) was measured by the quantum yield measuring device described above. The measurement results indicated optical characteristics including the fluorescence wavelength of 534 nm, the fluorescent half width of 40 nm, and the quantum yield of 45%.

Therefore, also in the present example, the QD 25 that emit green light and have the fluorescent half width of 45 nm or less and the fluorescence quantum yield of 35% or more could be obtained. Therefore, also in the present example, it is found that, by using the QD 25 as the QDs, the light-emitting element 1 that contains the Cd-free chalcopyrite-based QDs having the narrow fluorescent half width and the high fluorescence quantum yield and that emits green light can be provided.

Note that the composition of the reaction initial stage particles, the post-added element, the fluorescence wavelength, the fluorescent half width, the fluorescence quantum yield, and the S raw material as the S source in the present example are also collectively shown in Table 2 below.

### Example 11

The above-described Ag(OAc)-OLAm (concentration 0.2 M) 0.5 mL, gallium acetylacetonate (Ga(acac)₃) 73.4 mg, oleylamine (OLAm) 9.5 mL, and dodecanethiol (DDT) 0.3 mL were charged in a 100 mL reaction vessel. In an inert gas (N₂) atmosphere, the raw materials in the reaction vessel were then heated at 120° C. for 5 minutes while being stirred to be dissolved, and a solution was thereby obtained.

Next, the TETDS-OLAm (concentration 0.4 M) 0.5 mL was added to the solution in the reaction vessel from above the solution. Thereafter, the temperature of the solution in the reaction vessel was raised from 120° C. to 200° C., and the solution was stirred for 20 minutes in total. Thereafter, the obtained reaction solution (AgGaS dispersion (11A) containing AgGaS-based particles as the reaction initial stage particles) was cooled to ambient temperature.

The In(OAc)₃-OLAm/OLAc (concentration 0.2 M) 0.375 mL and S-ODE (concentration 0.2 M) 1.225 mL were added to the obtained reaction solution (AgGaS dispersion (11A)), and the mixture was heated while being stirred again at 270° C. for 10 minutes.

Thereafter, a mixed solution 4.5 mL obtained by mixing the GaCl₃/OLAc-ODE (molar ratio Ga:OLAc=1:1.5, concentration 0.1 M) 3 mL and the S-ODE (concentration 0.2 M) 1.5 mL was dropped to the reaction solution being heated while being stirred at 270° C. from above the reaction solution over 50 minutes. After completion of the dropping of the mixed solution, the reaction solution to which the mixed solution had been dropped was heated while being stirred for 70 minutes. Thereafter, the obtained reaction solution (AgInGaS dispersion (11B) containing AgInGaS-based QD 25) was cooled to ambient temperature.

Thereafter, trioctylphosphine (TOP) 3 mL was added to the reaction solution (AgInGaS dispersion (11B)), and the mixture was heated at 200° C. for 10 minutes. Thereafter, the obtained reaction solution (AgInGaS dispersion (11C) containing AgInGaS-based QD 25) was cooled to ambient temperature. Thereafter, the cleaning separation was performed on the QD 25 using toluene and ethanol. Thereafter, the QDs 25 were redispersed with toluene to obtain a QD dispersion (11D) containing the QD 25. Then, the fluorescence wavelength and the fluorescent half width of the QD 25 in the QD dispersion (11D) were measured by the fluorescence spectrometer described above. The fluorescence quantum yield of the QD 25 in the QD dispersion (11D) was measured by the quantum yield measuring device described above. The measurement results indicated optical characteristics including the fluorescence wavelength of 536.5 nm, the fluorescent half width of 29.4 nm, and the quantum yield of 71%.

Therefore, also in the present example, the QD 25 that emit green light and have the fluorescent half width of 45 nm or less and the fluorescence quantum yield of 35% or more could be obtained. Therefore, also in the present example, it is found that, by using the QD 25 as the QDs, the light-emitting element 1 that contains the Cd-free chalcopyrite-based QDs having the narrow fluorescent half width and the high fluorescence quantum yield and that emits green light can be provided.

Note that the composition of the reaction initial stage particles, the post-added element, the fluorescence wavelength, the fluorescent half width, the fluorescence quantum yield, and the S raw material as the S source in the present example are also collectively shown in Table 2 below.

Note that the composition of the reaction initial stage particles, the post-added element, the fluorescence wavelength, the fluorescent half width, the fluorescence quantum yield, and the S raw material as the S source in the present example are also collectively shown in Table 2 below.

### Example 12

The above-described Ag(OAc)-OLAm (concentration 0.2 M) 0.5 mL, gallium acetylacetonate (Ga(acac)₃) 91.8 mg, oleylamine (OLAm) 9.5 mL, and dodecanethiol (DDT) 0.5 mL were charged in a 100 mL reaction vessel. In an inert gas (N₂) atmosphere, the raw materials in the reaction vessel were then heated at 200° C. for 5 minutes while being stirred to be dissolved, and a solution was thereby obtained.

Next, the TETDS-OLAm (concentration 0.4 M) 1 mL was added to the solution in the reaction vessel from above the solution. Thereafter, the solution in the reaction vessel was heated at a temperature of 200° C. for 40 minutes while being stirred. Thereafter, the obtained reaction solution (AgGaS dispersion (12A) containing AgGaS-based particles as the reaction initial stage particles) was cooled to ambient temperature.

In(OAc)₃-OLAm/OLAc (concentration 0.2 M) 0.375 mL and S-ODE (concentration 0.2 M) 0.375 mL were added to the obtained reaction solution (AgGaS dispersion (12A)), and the mixture was heated while being stirred again at 270° C. for 10 minutes.

Thereafter, toluene 3 mL and ethanol 30 mL were added to the obtained reaction solution (AgInGaS dispersion (12B) containing the AgInGaS-based QD 25), and the cleaning separation of the QD 25 was performed. Thereafter, the QD 25 were redispersed with oleylamine (OLAm) 10 mL. Thus, an AgInGaS dispersion (12C) containing the AgInGaS-based QD 25 was obtained.

Thereafter, a mixed solution 4.5 mL obtained by mixing the GaCl₃/OLAc-ODE (molar ratio Ga:OLAc=1:1.5, concentration 0.1 M) 3 mL and the S-ODE solution (concentration 0.2 M) 1.5 mL was dropped to the AgInGaS dispersion (12C) from above the dispersion over 50 minutes while the AgInGaS dispersion (12C) was heated while being stirred at 270° C. After completion of the dropping of the mixed solution, the reaction solution to which the mixed solution had been dropped was heated while being stirred for 70 minutes. Thereafter, the obtained reaction solution (AgInGaS dispersion (12D) containing the AgInGaS-based QD 25) was cooled to ambient temperature.

Thereafter, trioctylphosphine (TOP) 3 mL was added to the reaction solution (AgInGaS dispersion (12D)), and the mixture was heated at 200° C. for 10 minutes, and thus the QD 25 were purified. Thereafter, the obtained reaction solution (AgInGaS dispersion (12E) containing the AgInGaS-based QD 25) was cooled to ambient temperature. Thereafter, the cleaning separation of the QD 25 was performed using toluene and ethanol. Thereafter, the QD 25 were redispersed with trioctylphosphine (TOP) to obtain a QD dispersion (12F) containing the QD 25. Then, the fluorescence wavelength and the fluorescent half width of the QD 25 in the QD dispersion (12F) were measured by the fluorescence spectrometer described above. The fluorescence quantum yield of the QD 25 in the QD dispersion (12F) was measured by the quantum yield measuring device. As shown in FIG. 12, the measurement results indicated optical characteristics including the fluorescence wavelength of 530.5 nm, the fluorescent half width of 38 nm, and the quantum yield of 86%.

Therefore, also in the present example, the QD 25 that emit green light and have the fluorescent half width of 45 nm or less and the fluorescence quantum yield of 35% or more could be obtained. Therefore, also in the present example, it is found that, by using the QD 25 as the QDs, the light-emitting element 1 that contains the Cd-free chalcopyrite-based QDs having the narrow fluorescent half width and the high fluorescence quantum yield and that emits green light can be provided.

Note that the composition of the reaction initial stage particles, the post-added element, the fluorescence wavelength, the fluorescent half width, the fluorescence quantum yield, and the S raw material as the S source in the present example are also collectively shown in Table 2 below.

### Example 13

The above-described Ag(OAc)-OLAm (concentration 0.2 M) 0.5 mL, gallium acetylacetonate (Ga(acac)₃) 55 mg, oleylamine (OLAm) 9.5 mL, and dodecanethiol (DDT) 0.5 mL were charged in a 100 mL reaction vessel. In an inert gas (N₂) atmosphere, the raw materials in the reaction vessel were then heated at 200° C. for 5 minutes while being stirred to be dissolved, and a solution was thereby obtained.

Next, the TETDS-OLAm (concentration 0.4 M) 0.5 mL was added to the solution in the reaction vessel from above the solution. Thereafter, the solution in the reaction vessel was heated at a temperature of 200° C. for 40 minutes while being stirred. Thereafter, the obtained reaction solution (AgGaS dispersion (13A) containing AgGaS-based particles as the reaction initial stage particles) was cooled to ambient temperature.

In(OAc)₃-OLAm/OLAc (concentration 0.2 M) 0.375 mL and S-ODE (concentration 0.2 M) 1.125 mL were added to the obtained reaction solution (AgGaS dispersion (13A)), and the mixture was heated while being stirred again at 300° C. for 10 minutes.

Thereafter, a mixed solution 4.641 mL obtained by mixing the GaCl₃/OLAc-ODE (molar ratio Ga:OLAc=1:3, concentration 0.1 M) 3 mL, the S-ODE (concentration 0.2 M) 1.5 mL, and oleylamine (OLAm) 0.141 mL was dropped to the reaction solution being heated while being stirred at 300° C. from above the reaction solution over 50 minutes. After completion of the dropping of the mixed solution, the reaction solution to which the mixed solution had been dropped was heated while being stirred for 20 minutes. Thereafter, the obtained reaction solution (AgInGaS dispersion (13B) containing AgInGaS-based QD 25) was cooled to ambient temperature.

Thereafter, the S-ODE solution (concentration 0.2 M) 1.5 mL was added to the reaction solution (AgInGaS dispersion (13B)), and the mixture was heated while being stirred at 200° C. for 30 minutes. Thereafter, the obtained reaction solution (AgInGaS dispersion (13C) containing AgInGaS-based QD 25) was cooled to ambient temperature.

Thereafter, the reaction solution (AgInGaS dispersion (13C)) was centrifuged at 5500 rpm for 3 minutes using a centrifuge, and a supernatant liquid was collected. Trioctylphosphine (TOP) 3 mL was added to the collected supernatant liquid, and the mixture was heated at 200° C. for 10 minutes. Thereafter, the obtained reaction solution (AgInGaS dispersion (13D) containing AgInGaS-based QD 25) was cooled to ambient temperature.

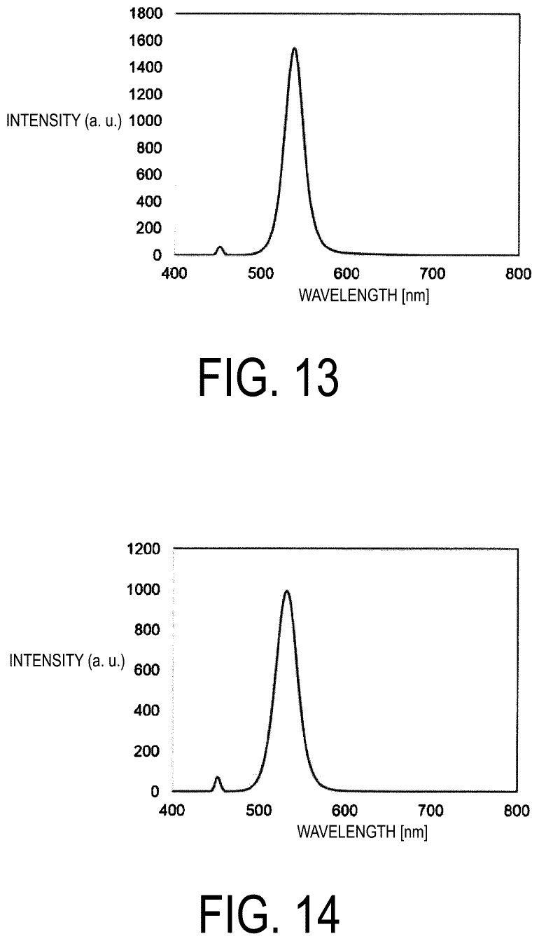

Thereafter, toluene 1 mL and ethanol 1.5 mL were added to the reaction solution (AgInGaS dispersion (13D)) 1 mL, and the mixture was centrifuged at 5500 rpm for 3 minutes using the centrifuge, and a supernatant liquid was collected. Ethanol 2 mL was added to the collected supernatant liquid, and the mixture was centrifuged at 5500 rpm for 3 minutes. Thus, the cleaning separation of the QD 25 was performed. Thereafter, the QD 25 were redispersed with toluene to obtain a QD dispersion (13E) containing the QD 25. Then, the fluorescence wavelength and the fluorescent half width of the QD 25 in the QD dispersion (13E) were measured by the fluorescence spectrometer described above. The fluorescence quantum yield of the QD 25 in the QD dispersion (13E) was measured by the quantum yield measuring device described above. As shown in FIG. 13, the measurement results indicated optical characteristics including the fluorescence wavelength of 537.5 nm, the fluorescent half width of 25 nm, and the quantum yield of 63%. Note that, as described above, the cleaning separation indicates the step of separation by controlling the degree of aggregation due to the difference in the coordination state of the ligands 21 coordinated to the QD 25 by the ratio of toluene and ethanol. Through the centrifugal separation and the cleaning separation, only the QD 25 to which the ligands 21 were coordinated in a well-balanced manner could be collected, and as a result, as described above, favorable light-emission characteristics having high quantum yields could be obtained.

Therefore, also in the present example, the QD 25 that emit green light and have the fluorescent half width of 45 nm or less and the fluorescence quantum yield of 35% or more could be obtained. Therefore, also in the present example, it is found that, by using the QD 25 as the QDs, the light-emitting element 1 that contains the Cd-free chalcopyrite-based QDs having the narrow fluorescent half width and the high fluorescence quantum yield and that emits green light can be provided.

Note that the composition of the reaction initial stage particles, the post-added element, the fluorescence wavelength, the fluorescent half width, the fluorescence quantum yield, and the S raw material as the S source in the present example are also collectively shown in Table 2 below.

### Example 14

The above-described Ag(OAc)-OLAm (concentration 0.2 M) 0.5 mL, gallium acetylacetonate (Ga(acac)₃) 73.4 mg, oleylamine (OLAm) 9.5 mL, and dodecanethiol (DDT) 0.5 mL were charged in a 100 mL reaction vessel. In an inert gas (N₂) atmosphere, the raw materials in the reaction vessel were then heated at 200° C. for 5 minutes while being stirred to be dissolved, and a solution was thereby obtained.

Next, the TETDS-OLAm (concentration 0.4 M) 0.5 mL was added to the solution in the reaction vessel from above the solution. Thereafter, the solution in the reaction vessel was heated at a temperature of 200° C. for 40 minutes while being stirred. Thereafter, the obtained reaction solution (AgGaS dispersion (14A) containing AgGaS-based particles as the reaction initial stage particles) was cooled to ambient temperature.

In(OAc)₃-OLAm/OLAc (concentration 0.2 M) 0.6 mL and S-ODE (concentration 0.2 M) 1.8 mL were added to the obtained reaction solution (AgGaS dispersion (14A)), and the mixture was heated while being stirred again at 290° C. for 10 minutes.

Thereafter, a mixed solution 8.1 mL obtained by mixing the GaCl₃/OLAc-ODE (molar ratio Ga:OLAc=1:3, concentration 0.1 M) 3.6 mL, the S-ODE (concentration 0.2 M) 1.8 mL, and oleylamine (OLAm) 2.7 mL was dropped to the reaction solution being heated while being stirred at 290° C. from above the reaction solution over 50 minutes. After completion of the dropping of the mixed solution, the reaction solution to which the mixed solution had been dropped was heated while being stirred for 20 minutes. Thereafter, the obtained reaction solution (AgInGaS dispersion (14B) containing AgInGaS-based QD 25) was cooled to ambient temperature.

Thereafter, the reaction solution (AgInGaS dispersion (14B)) was centrifuged at 5500 rpm for 3 minutes using the centrifuge, and a supernatant liquid was collected. Trioctylphosphine (TOP) 3 mL was added to the collected supernatant liquid, and the mixture was heated at 180° C. for 10 minutes. Thereafter, the obtained reaction solution (AgInGaS dispersion (14C) containing AgInGaS-based QD 25) was cooled to ambient

Thereafter, toluene 1 mL and ethanol 1.5 mL were added to the reaction solution (AgInGaS dispersion (14C)) 1 mL, and the mixture was centrifuged at 5500 rpm for 3 minutes using the centrifuge, and a supernatant liquid was collected. Ethanol 2 mL was added to the collected supernatant liquid, and the mixture was centrifuged at 5500 rpm for 3 minutes, and thus the cleaning separation of the QD 25 was performed. Thereafter, the QD 25 were redispersed with toluene to obtain a QD dispersion (14D) containing the QD 25. Then, the fluorescence wavelength and the fluorescent half width of the QD 25 in the QD dispersion (14D) were measured by the fluorescence spectrometer described above. The fluorescence quantum yield of the QD 25 in the QD dispersion (14D) was measured by the quantum yield measuring device described above. As shown in FIG. 14, the measurement results indicated optical characteristics including the fluorescence wavelength of 531.0 nm, the fluorescent half width of 29.3 nm, and the quantum yield of 85%.

Therefore, also in the present example, the QD 25 that emit green light and have the fluorescent half width of 45 nm or less and the fluorescence quantum yield of 35% or more could be obtained. Therefore, also in the present example, it is found that, by using the QD 25 as the QDs, the light-emitting element 1 that contains the Cd-free chalcopyrite-based QDs having the narrow fluorescent half width and the high fluorescence quantum yield and that emits green light can be provided.

Note that the composition of the reaction initial stage particles, the post-added element, the fluorescence wavelength, the fluorescent half width, the fluorescence quantum yield, and the S raw material as the S source in the present example are also collectively shown in Table 2 below.

### Example 15

The above-described Ag(OAc)-OLAm (concentration 0.2 M) 0.5 mL, gallium acetylacetonate (Ga(acac)₃) 73.4 mg, oleylamine (OLAm) 9.5 mL, and dodecanethiol (DDT) 0.5 mL were charged in a 100 mL reaction vessel. In an inert gas (N₂) atmosphere, the raw materials in the reaction vessel were then heated at 200° C. for 5 minutes while being stirred to be dissolved, and a solution was thereby obtained.

Next, the TETDS-OLAm (concentration 0.4 M) 0.5 mL was added to the solution in the reaction vessel from above the solution. Thereafter, the solution in the reaction vessel was heated at a temperature of 200° C. for 40 minutes while being stirred. Thereafter, the obtained reaction solution (AgGaS dispersion (15A) containing AgGaS-based particles as the reaction initial stage particles) was cooled to ambient temperature.

In(OAc)₃-OLAm/OLAc (concentration 0.2 M) 0.5 mL and S-ODE (concentration 0.2 M) 1.5 mL were added to the obtained reaction solution (AgGaS dispersion (15A)), and the mixture was heated while being stirred again at 290° C. for 10 minutes.

Thereafter, a mixed solution 6.5 mL obtained by mixing the GaCl₃/OLAc-OLAm (molar ratio Ga:OLAc=1:3, concentration 0.1 M) 3 mL, the TETDS-OLAm (TETDS-OLAm solution) (concentration 0.4 M) 0.5 mL, and oleylamine (OLAm) 3 mL was dropped to the reaction solution being heated while being stirred at 290° C. from above the reaction solution over 80 minutes. After completion of the dropping of the mixed solution, the reaction solution to which the mixed solution had been dropped was heated while being stirred for 10 minutes. Thereafter, the obtained reaction solution (AgInGaS dispersion (15B) containing AgInGaS-based QD 25) was cooled to ambient temperature.

Thereafter, the reaction solution (AgInGaS dispersion (15B)) was centrifuged at 5500 rpm for 3 minutes using the centrifuge, and a supernatant liquid was collected. Trioctylphosphine (TOP) 3 mL was added to the collected supernatant liquid, and the mixture was heated at 180° C. for 10 minutes. Thereafter, the obtained reaction solution (AgInGaS dispersion (15C) containing AgInGaS-based QD 25) was cooled to ambient temperature.

Thereafter, toluene 1 mL and ethanol 1.5 mL were added to the reaction solution (AgInGaS dispersion (15C)) 1 mL, and the mixture was centrifuged at 5500 rpm for 3 minutes using the centrifuge, and a supernatant liquid was collected. Ethanol 2 mL was added to the collected supernatant liquid, and the mixture was centrifuged again at 5500 rpm for 3 minutes using the centrifuge, and thus the cleaning separation of the QD 25 was performed. Thereafter, the QD 25 were redispersed with toluene to obtain a QD dispersion (15D) containing the QD 25. Then, the fluorescence wavelength and the fluorescent half width of the QD 25 in the QD dispersion (15D) were measured by the fluorescence spectrometer described above. The fluorescence quantum yield of the QDs 25 in the QD dispersion (15D) was measured by the quantum yield measuring device described above. The measurement results indicated optical characteristics including the fluorescence wavelength of 529.5 nm, the fluorescent half width of 30.8 nm, and the quantum yield of 71%.

Thereafter, the reaction solution (AgInGaS dispersion (15C)) was heated at 200° C. for 5 minutes. Thereafter, a mixed solution 2 mL obtained by mixing the Zn(OAc)₂-OLAc/TOP (concentration 0.8 M) 0.075 mL, the S-TOP (concentration 0.2 M) 0.6 mL, and oleylamine (OLAm) 1.325 mL was dropped to the reaction solution being heated while being stirred at 200° C. from above the reaction solution over 120 minutes. After completion of the dropping of the mixed solution, the obtained reaction solution (ZnAgInGaS dispersion (15D) containing ZnAgInGaS-based QD 25) was cooled to ambient temperature.

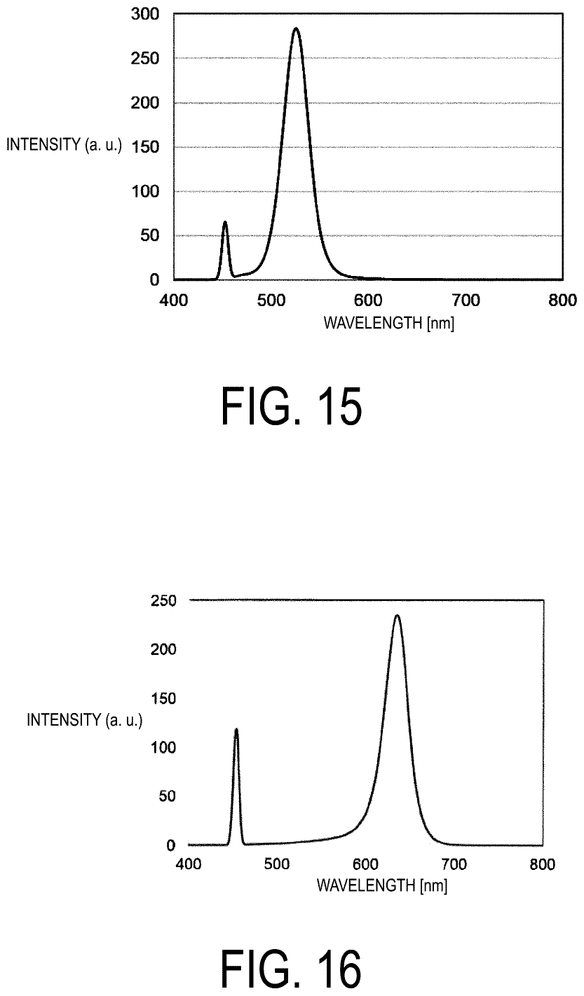

Thereafter, toluene 1 mL and ethanol 1.6 mL were added to the reaction solution (ZnAgInGaS dispersion (15D)) 1 mL, and the mixture was centrifuged at 5500 rpm for 3 minutes using the centrifuge, and a supernatant liquid was collected. Ethanol 2 mL was added to the collected supernatant liquid, and the mixture was centrifuged at 5500 rpm for 3 minutes, and thus the cleaning separation of the QD 25 was performed. Thereafter, the QD 25 were redispersed with toluene to obtain a QD dispersion (15E) containing the QD 25. Then, the fluorescence wavelength and the fluorescent half width of the QD 25 in the QD dispersion (15E) were measured by the fluorescence spectrometer described above. The fluorescence quantum yield of the QD 25 in the QD dispersion (15E) was measured by the quantum yield measuring device described above. As shown in FIG. 15, the measurement results indicated optical characteristics including the fluorescence wavelength of 528 nm, the fluorescent half width of 31 nm, and the quantum yield of 84%.

Therefore, also in the present example, the QD 25 that emit green light and have the fluorescent half width of 45 nm or less and the fluorescence quantum yield of 35% or more could be obtained. Therefore, also in the present example, it is found that, by using the QD 25 as the QDs, the light-emitting element 1 that contains the Cd-free chalcopyrite-based QDs having the narrow fluorescent half width and the high fluorescence quantum yield and that emits green light can be provided.

Note that the composition of the reaction initial stage particles, the post-added element, the fluorescence wavelength, the fluorescent half width, the fluorescence quantum yield, and the S raw material as the S source in the present example are also collectively shown in Table 2 below.

### Example 16

The above-described Ag(OAc)-OLAm (concentration 0.2 M) 0.5 mL, gallium acetylacetonate (Ga(acac)₃) 55.5 mg, oleylamine (OLAm) 20 mL, and dodecanethiol (DDT) 3 mL were charged in a 100 mL reaction vessel. In an inert gas (N₂) atmosphere, the raw materials in the reaction vessel were then heated at 150° C. for 5 minutes while being stirred to be dissolved, and a solution was thereby obtained.

Next, the Se-OLAm/DDT (concentration 0.7 M) 0.36 mL was added to the solution in the reaction vessel from above the solution. Thereafter, the solution in the reaction vessel was stirred at a temperature of 150° C. for 10 minutes. Thereafter, the obtained reaction solution (AgGaSe dispersion (16A) containing AgGaSe-based particles as the reaction initial stage particles) was once cooled to ambient temperature, then heated while being stirred at 320° C. for 20 minutes, and then cooled again to ambient temperature.

Thereafter, the reaction solution was centrifuged at 5500 rpm for 3 minutes by the centrifuge to precipitate the reaction initial stage particles. The precipitated reaction initial stage particles were redispersed with toluene, then methanol and ethanol were added thereto, and the mixture was centrifuged at 5500 rpm for 3 minutes by the centrifuge. Thus, the reaction initial stage particles were precipitated again. Thereafter, oleylamine (OLAm) 9.5 mL was added to the precipitated reaction initial stage particles, and the reaction initial stage particles were redispersed with the oleylamine (OLAm). As a result, an AgGaSe dispersion (16B) in which the reaction initial stage particles were dispersed in the oleylamine (OLAm) was obtained.

Thereafter, a mixed solution 3.64 mL obtained by mixing the GaCl₃/OLAc-OLAm (molar ratio Ga:OLAc=1:1.5, concentration 0.1 M) 3 mL and the Se-OLAm/DDT (concentration 0.7 M) 0.64 mL was dropped to the AgGaSe dispersion (16B) from above the dispersion (16B) over 20 minutes while the AgGaSe dispersion (16B) was heated while being stirred at 290° C. After completion of the dropping of the mixed solution, the reaction solution to which the mixed solution had been dropped was heated while being stirred for 100 minutes. Thereafter, the obtained reaction solution (AgGaSe dispersion (16C) containing the AgGaSe-based particles) was cooled to ambient temperature.

The fluorescence wavelength and the fluorescent half width of the particles in the obtained reaction solution (AgGaSe dispersion (16C)) were measured by the fluorescence spectrometer described above. The measurement results indicated optical characteristics including the fluorescence wavelength of 639 nm and the fluorescent half width of 28.5 nm.

Thereafter, trioctylphosphine (TOP) 8 mL was added to the reaction solution (AgGaSe dispersion (16C)), and the mixture was heated and stirred at 200° C. for 5 minutes.

Thereafter, a mixed solution 2 mL obtained by mixing the Zn(OAc)₂-OLAc/TOP (concentration 0.8 M) 1 mL and the S-OLAm/DDT (concentration 0.8 M) 1 mL was dropped to the reaction solution being heated while being stirred at 200° C. from above the reaction solution over 20 minutes. After completion of the dropping of the mixed solution, the reaction solution to which the mixed solution had been dropped was heated while being stirred for 130 minutes. Thereafter, the obtained reaction solution (QD dispersion (16D) containing the ZnAgGaSeS-based QD 25) was cooled to ambient temperature.

Thereafter, trioctylphosphine (TOP) 2 mL was added to the reaction solution (QD dispersion (16D)) 2 mL. Thereafter, the reaction solution to which the TOP was added was centrifuged at 5500 rpm for 3 minutes by the centrifuge to remove precipitates. Thus, a QD dispersion (16E) containing the QD 25 was obtained. The fluorescence wavelength and the fluorescent half width of the QD 25 in the obtained QD dispersion (16E) were measured by the fluorescence spectrometer. The fluorescence quantum yield of the QDs 25 in the QD dispersion (16E) was measured by the quantum yield measuring device described above. As shown in FIG. 16, the measurement results indicated optical characteristics including the fluorescence wavelength of 642 nm, the fluorescent half width of 33 nm, and the quantum yield of 76%.

As described above, according to the present example, the QD 25 that emit red light and have the fluorescent half width of 45 nm or less and the fluorescence quantum yield of 35% or more could be obtained. Therefore, according to the present example, it is found that, by using the QD 25 as the QDs, the light-emitting element 1 that contains the Cd-free chalcopyrite-based QDs having the narrow fluorescent half width and the high fluorescence quantum yield and that emits red light can be provided.

Note that the composition of the reaction initial stage particles, the post-added element, the fluorescence wavelength, the fluorescent half width, the fluorescence quantum yield, the S raw material as the S source, and the Se raw material as the Se source in the present example are collectively shown in Table 3 below. Note that, also in Table 3, “composition of the reaction initial stage particles”, “fluorescence wavelength”, “fluorescent half width”, and “fluorescence quantum yield” are denoted by “initial stage particle composition”, “wavelength”, “half width”, and “PLQY”, respectively.

### Example 17

The above-described Ag(OAc)-OLAm (concentration 0.2 M) 0.5 mL, gallium acetylacetonate (Ga(acac)₃) 55.5 mg, oleylamine (OLAm) 20 mL, and dodecanethiol (DDT) 3 mL were charged in a 100 mL reaction vessel. In an inert gas (N₂) atmosphere, the raw materials in the reaction vessel were then heated at 150° C. for 5 minutes while being stirred to be dissolved, and a solution was thereby obtained.

Next, the Se-OLAm/DDT (concentration 0.7 M) 0.36 mL was added to the solution in the reaction vessel from above the solution. Thereafter, the solution in the reaction vessel was stirred at a temperature of 150° C. for 10 minutes. Thereafter, the obtained reaction solution (AgGaSe dispersion (17A) containing AgGaSe-based particles as the reaction initial stage particles) was once cooled to ambient temperature, then heated while being stirred at 320° C. for 20 minutes, and then cooled again to ambient temperature.

Thereafter, the reaction solution was centrifuged at 5500 rpm for 3 minutes by the centrifuge to precipitate the reaction initial stage particles. The precipitated reaction initial stage particles were redispersed with toluene, then methanol and ethanol were added thereto, and the mixture was centrifuged at 5500 rpm for 3 minutes by the centrifuge. Thus, the reaction initial stage particles were precipitated again. Thereafter, oleylamine (OLAm) 9.5 mL was added to the precipitated reaction initial stage particles, and the reaction initial stage particles were redispersed with the oleylamine (OLAm). As a result, a dispersion (17B) in which the reaction initial stage particles were dispersed in the oleylamine (OLAm) was obtained.

Thereafter, a mixed solution 3.64 mL obtained by mixing the GaCl₃/LAc-OLAm (molar ratio Ga:OLAc=1:1.5, concentration 0.1 M) 3 mL and the Se-OLAm/DDT (concentration 0.7 M) 0.64 mL was dropped to the dispersion (17B) from above the dispersion (17B) over 30 minutes while the dispersion (17B) was heated while being stirred at 290° C. After completion of the dropping of the mixed solution, the reaction solution to which the mixed solution had been dropped was heated while being stirred for 90 minutes. Thereafter, the obtained reaction solution (AgGaSe dispersion (17C) containing the AgGaSe-based particles) was cooled to ambient temperature.

Thereafter, trioctylphosphine (TOP) 8 mL was added to the reaction solution (AgGaSe dispersion (17C)), and the mixture was heated and stirred at 150° C. for 5 minutes.

Then, the Se-OLAm/DDT (concentration 0.7 M) 0.34 mL was added to the reaction solution being heated while being stirred at 150° C. from above the reaction solution, and the mixture was heated at 150° C. for 40 minutes.

Then, the Se-OLAm/DDT (concentration 0.7 M) 0.17 mL and the S-OLAm/DDT (concentration 0.8 M) 0.15 mL were added to the reaction solution, and the mixture was heated at 150° C. for 40 minutes. Thereafter, the obtained reaction solution (QD dispersion (17C) containing the AgGaSSe-based QD 25) was cooled to ambient temperature.

Thereafter, trioctylphosphine (TOP) 0.4 mL was added to the reaction solution (QD dispersion (17C)) 2 mL. Thereafter, the reaction solution to which the TOP was added was centrifuged at 5500 rpm for 3 minutes by the centrifuge to remove precipitates. Thus, a QD dispersion (17D) containing the QD 25 was obtained. The fluorescence wavelength and the fluorescent half width of the QD 25 in the obtained QD dispersion (17D) were measured by the fluorescence spectrometer. The fluorescence quantum yield of the QD 25 in the QD dispersion (17D) was measured by the quantum yield measuring device described above. The measurement results indicated optical characteristics including the fluorescence wavelength of 639 nm, the fluorescent half width of 30.5 nm, and the quantum yield of 56%.

Therefore, also in the present example, the QD 25 that emit red light and have the fluorescent half width of 45 nm or less and the fluorescence quantum yield of 35% or more could be obtained. Therefore, also in the present example, it is found that, by using the QD 25 as the QDs, the light-emitting element 1 that contains the Cd-free chalcopyrite-based QDs having the narrow fluorescent half width and the high fluorescence quantum yield and that emits red light can be provided.

Note that the composition of the reaction initial stage particles, the post-added element, the fluorescence wavelength, the fluorescent half width, the fluorescence quantum yield, the S raw material as the S source, and the Se raw material as the Se source in the present example are also collectively shown in Table 3 below.

### Example 18

The above-described Ag(OAc)-OLAm (concentration 0.2 M) 0.5 mL, gallium acetylacetonate (Ga(acac)₃) 55.5 mg, oleylamine (OLAm) 20 mL, and dodecanethiol (DDT) 3 mL were charged in a 100 mL reaction vessel. In an inert gas (N₂) atmosphere, the raw materials in the reaction vessel were then heated at 150° C. for 5 minutes while being stirred to be dissolved, and a solution was thereby obtained.

Next, the Se-OLAm/DDT (concentration 0.7 M) 0.36 mL was added to the solution in the reaction vessel from above the solution. Thereafter, the solution in the reaction vessel was stirred at a temperature of 150° C. for 10 minutes. Thereafter, the obtained reaction solution (AgGaSe dispersion (18A) containing AgGaSe-based particles as the reaction initial stage particles) was once cooled to ambient temperature, then heated while being stirred at 320° C. for 20 minutes, and then cooled again to ambient

Thereafter, the reaction solution was centrifuged at 5500 rpm for 3 minutes by the centrifuge to precipitate the reaction initial stage particles. The precipitated reaction initial stage particles were redispersed with toluene, then methanol and ethanol were added thereto, and the mixture was centrifuged at 5500 rpm for 3 minutes by the centrifuge. Thus, the reaction initial stage particles were precipitated again. Thereafter, oleylamine (OLAm) 9.5 mL was added to the precipitated reaction initial stage particles, and the reaction initial stage particles were redispersed with the oleylamine (OLAm). As a result, a dispersion (18B) in which the reaction initial stage particles were dispersed in the oleylamine (OLAm) was obtained.

Thereafter, a mixed solution 3.64 mL obtained by mixing the GaCl₃/LAc-OLAm (molar ratio Ga:OLAc=1:1.5, concentration 0.1 M) 3 mL and the Se-OLAm/DDT (concentration 0.7 M) 0.64 mL was dropped to the dispersion (18B) from above the dispersion (18B) over 30 minutes while the dispersion (18B) was heated while being stirred at 290° C. After completion of the dropping of the mixed solution, the reaction solution to which the mixed solution had been dropped was heated while being stirred for 90 minutes. Thereafter, the obtained reaction solution (AgGaSe dispersion (18C) containing the AgGaSe-based particles) was cooled to ambient temperature.

Thereafter, trioctylphosphine (TOP) 8 mL was added to the reaction solution (AgGaSe dispersion (18C)), and the mixture was heated and stirred at 150° C. for 5 minutes.

Then, the Se-OLAm/DDT (concentration 0.7 M) 0.34 mL was added to the reaction solution being heated while being stirred at 150° C. from above the reaction solution, and the mixture was heated at 150° C. for 20 minutes.

Then, the Zn(OAc)₂-OLAc/TOP (concentration 0.8 M) 0.3 mL was added to the reaction solution, and the mixture was heated at 150° C. for 20 minutes. Subsequently, the Se-OLAm/DDT (concentration 0. 7 M) 0.17 mL and the S-OLAm/DDT (concentration 0.8 M) 0.15 mL were added to the reaction solution from above the reaction solution, and the mixture was heated at 150° C. for 20 minutes. Then, the Zn(OAc)₂-OLAc/TOP (concentration 0.8 M) 0.3 mL was added to the reaction solution, and the mixture was heated at 150° C. for 20 minutes. Thereafter, the obtained reaction solution (QD dispersion (18D) containing the ZnAgGaS Se-based QD 25) was cooled to ambient temperature.

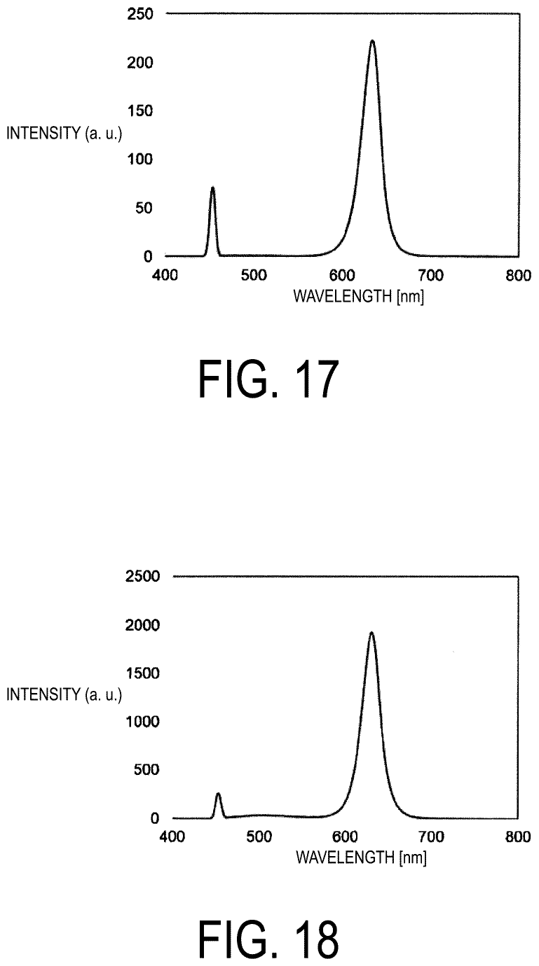

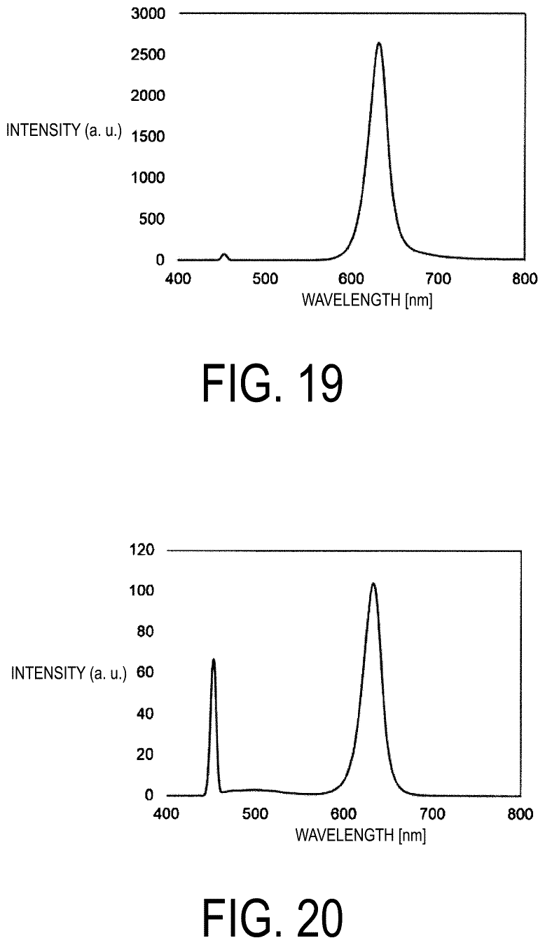

Thereafter, trioctylphosphine (TOP) 0.4 mL was added to the reaction solution (QD dispersion (18D)) 2 mL. Thereafter, the reaction solution to which the TOP was added was centrifuged at 5500 rpm for 3 minutes by the centrifuge to remove precipitates. Thus, a QD dispersion (18E) containing the QD 25 was obtained. The fluorescence wavelength and the fluorescent half width of the QD 25 in the obtained QD dispersion (18E) were measured by the fluorescence spectrometer described above. The fluorescence quantum yield of the QD 25 in the QD dispersion (18E) was measured by the quantum yield measuring device described above. As shown in FIG. 17, the measurement results indicated optical characteristics including the fluorescence wavelength of 633 nm, the fluorescent half width of 27 nm, and the quantum yield of 81%.

Therefore, also in the present example, the QD 25 that emit red light and have the fluorescent half width of 45 nm or less and the fluorescence quantum yield of 35% or more could be obtained. Therefore, also in the present example, it is found that, by using the QD 25 as the QDs, the light-emitting element 1 that contains the Cd-free chalcopyrite-based QDs having the narrow fluorescent half width and the high fluorescence quantum yield and that emits red light can be provided.

Note that the composition of the reaction initial stage particles, the post-added element, the fluorescence wavelength, the fluorescent half width, the fluorescence quantum yield, the S raw material as the S source, and the Se raw material as the Se source in the present example are also collectively shown in Table 3 below.

### Example 19

The above-described Ag(OAc)-OLAm (concentration 0.2 M) 0.5 mL, gallium acetylacetonate (Ga(acac)₃) 55.5 mg, oleylamine (OLAm) 20 mL, and dodecanethiol (DDT) 3 mL were charged in a 100 mL reaction vessel. In an inert gas (N₂) atmosphere, the raw materials in the reaction vessel were then heated at 150° C. for 5 minutes while being stirred to be dissolved, and a solution was thereby obtained.

Next, the Se-OLAm/DDT (concentration 0.7 M) 0.36 mL was added to the solution in the reaction vessel from above the solution. Thereafter, the solution in the reaction vessel was stirred at a temperature of 150° C. for 10 minutes. Thereafter, the obtained reaction solution (AgGaSe dispersion(19A) containing AgGaSe-based particles as the reaction initial stage particles) was once cooled to ambient temperature, then heated while being stirred at 320° C. for 20 minutes, and then cooled again to ambient temperature.

Thereafter, the reaction solution was centrifuged at 5500 rpm for 3 minutes by the centrifuge to precipitate the reaction initial stage particles. The precipitated reaction initial stage particles were redispersed with toluene, and the cleaning separation of the reaction initial stage particles was performed by using methanol and ethanol. After that, oleylamine (OLAm) 9.5 mL was added to the reaction initial stage particles, and the reaction initial stage particles were redispersed with the oleylamine (OLAm). As a result, a dispersion (19B) in which the reaction initial stage particles were dispersed in the oleylamine (OLAm) was obtained.

Thereafter, a mixed solution 3.64 mL obtained by mixing the GaCl₃/LAc-OLAm (molar ratio Ga:OLAc=1:1.5, concentration 0.1 M) 3 mL and the Se-OLAm/DDT (concentration 0.7 M) 0.64 mL was dropped to the dispersion (19B) from above the dispersion (19B) over 20 minutes while the dispersion (19B) was heated while being stirred at 290° C. After completion of the dropping of the mixed solution, the reaction solution to which the mixed solution had been dropped was heated while being stirred for 100 minutes. Thereafter, the obtained reaction solution (AgGaSe dispersion (19C) containing the AgGaSe-based particles) was cooled to ambient temperature.

Thereafter, trioctylphosphine (TOP) 8 mL was added to the reaction solution (AgGaSe dispersion (19C)), and the mixture was heated and stirred at 150° C. for 5 minutes.

Then, the Se-OLAm/DDT (concentration 0.7 M) 0.34 mL was added to the reaction solution being heated while being stirred at 150° C. from above the reaction solution, and the mixture was heated at 150° C. for 20 minutes.

Then, the Zn(OAc)₂-OLAm (concentration 0.4 M) 0.6 mL was added to the reaction solution, and the mixture was heated at 150° C. for 20 minutes. Subsequently, the Se-OLAm/DDT (concentration 0.7 M) 0.17 mL and the S-OLAm/DDT (concentration 0.8 M) 0.15 mL were added to the reaction solution from above the reaction solution, and the mixture was heated at 150° C. for 20 minutes. Then, the Zn(OAc)₂-OLAm (concentration 0.4 M) 0.6 mL was added to the reaction solution, and the mixture was heated at 150° C. for 20 minutes. Thereafter, the obtained reaction solution (QD dispersion (19D) containing the ZnAgGaS Se-based QD 25) was cooled to ambient temperature.

Thereafter, trioctylphosphine (TOP) 0.4 mL was added to the reaction solution (QD dispersion (19D)) 2 mL. Thereafter, the reaction solution to which the TOP was added was centrifuged at 5500 rpm for 3 minutes by the centrifuge to remove precipitates. Thus, a QD dispersion (19E) containing the QD 25 was obtained. The fluorescence wavelength and the fluorescent half width of the QD 25 in the obtained QD dispersion (19E) were measured by the fluorescence spectrometer described above. The fluorescence quantum yield of the QD 25 in the QD dispersion (19E) was measured by the quantum yield measuring device described above. As shown in FIG. 18, the measurement results indicated optical characteristics including the fluorescence wavelength of 630.5 nm, the fluorescent half width of 24.5 nm, and the quantum yield of 70%.

Therefore, also in the present example, the QD 25 that emit red light and have the fluorescent half width of 45 nm or less and the fluorescence quantum yield of 35% or more could be obtained. Therefore, also in the present example, it is found that, by using the QD 25 as the QDs, the light-emitting element 1 that contains the Cd-free chalcopyrite-based QDs having the narrow fluorescent half width and the high fluorescence quantum yield and that emits red light can be provided.

Note that the composition of the reaction initial stage particles, the post-added element, the fluorescence wavelength, the fluorescent half width, the fluorescence quantum yield, the S raw material as the S source, and the Se raw material as the Se source in the present example are also collectively shown in Table 3 below.

### Example 20

The above-described Ag(OAc)-OLAm (concentration 0.2 M) 0.5 mL, gallium acetylacetonate (Ga(acac)₃) 53.3 mg, In(acac)₃-OLAm/OLAc (concentration 0.02 M) 0.25 mL, and dodecanethiol (DDT) 2.5 mL were charged in a 100 mL reaction vessel. In an inert gas (N₂) atmosphere, the raw materials in the reaction vessel were then heated at 150° C. for 5 minutes while being stirred to be dissolved, and a solution was thereby obtained.

Next, the Se-OLAm/DDT (concentration 0.7 M) 0.36 mL was added to the solution in the reaction vessel from above the solution. Thereafter, the solution in the reaction vessel was stirred at a temperature of 150° C. for 10 minutes. Thereafter, the obtained reaction solution (AgInGaSe dispersion (20A) containing AgInGaSe-based particles as the reaction initial stage particles) was once cooled to ambient temperature, then heated while being stirred at 320° C. for 60 minutes, and then cooled again to ambient temperature.

Thereafter, the reaction solution was centrifuged at 5500 rpm for 3 minutes by the centrifuge to precipitate the reaction initial stage particles. The precipitated reaction initial stage particles were redispersed with toluene, and the cleaning separation of the reaction initial stage particles was performed by using methanol and ethanol. After that, oleylamine (OLAm) 9.5 mL was added to the reaction initial stage particles, and the reaction initial stage particles were redispersed with the oleylamine (OLAm). As a result, a dispersion (20B) in which the reaction initial stage particles were dispersed in the oleylamine (OLAm) was obtained.

Thereafter, a mixed solution 3.57 mL obtained by mixing the GaCl₃/LAc-OLAm (molar ratio Ga:OLAc=1:1.5, concentration 0.1 M) 3 mL and the S-OLAm/DDT (concentration 0.8 M) 0.57 mL was dropped to the dispersion (20B) from above the dispersion (20B) over 30 minutes while the dispersion (20B) was heated while being stirred at 260° C. After completion of the dropping of the mixed solution, the reaction solution to which the mixed solution had been dropped was heated while being stirred for 150 minutes. Thereafter, the obtained reaction solution (AgInGaSe dispersion (20C) containing the AgInGaSe-based particles) was cooled to ambient temperature.

Then, Zn(OAc)₂-OLAc/TOP (concentration 0.8 M) 15 mL and S-OLAm/DDT (S-OLAm/DDT solution) (concentration 0.8 M) 15 mL were added to the reaction solution (AgInGaSe dispersion (20C)), and the mixture was heated and stirred at 150° C. for 5 minutes. Thereafter, trioctylphosphine (TOP) 3 mL was added to the reaction solution from above the reaction solution, and the mixture was heated at 150° C. for 10 minutes. Then, the Zn(OAc)₂-OLAc/TOP (concentration 0.8 M) 0.15 mL and S-OLAm/DDT (concentration 0.8 M) 0.15 mL were added to the reaction solution, and the mixture was heated at 150° C. for 20 minutes.

Thereafter, trioctylphosphine (TOP) 0.4 mL was added to the reaction solution 2 mL. Thereafter, the reaction solution was centrifuged at 5500 rpm for 3 minutes by the centrifuge to remove precipitates. As a result, a QD dispersion (20D) containing ZnAgInGaSSe-based QD 25 was obtained. The fluorescence wavelength and the fluorescent half width of the QD 25 in the obtained QD dispersion (20D) were measured by the fluorescence spectrometer. The fluorescence quantum yield of the QD 25 in the QD dispersion (20D) was measured by the quantum yield measuring device described above. As shown in FIG. 18, the measurement results indicated optical characteristics including the fluorescence wavelength of 631 nm, the fluorescent half width of 25 nm, and the quantum yield of 67%.

Therefore, also in the present example, the QD 25 that emit red light and have the fluorescent half width of 45 nm or less and the fluorescence quantum yield of 35% or more could be obtained. Therefore, also in the present example, it is found that, by using the QD 25 as the QDs, the light-emitting element 1 that contains the Cd-free chalcopyrite-based QDs having the narrow fluorescent half width and the high fluorescence quantum yield and that emits red light can be provided.

Note that the composition of the reaction initial stage particles, the post-added element, the fluorescence wavelength, the fluorescent half width, the fluorescence quantum yield, the S raw material as the S source, and the Se raw material as the Se source in the present example are also collectively shown in Table 3 below.

### Example 21

The above-described Ag(OAc)-OLAm (concentration 0.2 M) 0.5 mL, gallium acetylacetonate (Ga(acac)₃) 55.5 mg, oleylamine (OLAm) 20 mL, and dodecanethiol (DDT) 3 mL were charged in a 100 mL reaction vessel. In an inert gas (N₂) atmosphere, the raw materials in the reaction vessel were then heated at 150° C. for 5 minutes while being stirred to be dissolved, and a solution was thereby obtained.

Next, the Se-OLAm/DDT (concentration 0.7 M) 0.36 mL was added to the solution in the reaction vessel from above the solution. Thereafter, the solution in the reaction vessel was stirred at a temperature of 150° C. for 10 minutes. Thereafter, the obtained reaction solution (AgGaSe dispersion (21A) containing AgGaSe-based particles as the reaction initial stage particles) was once cooled to ambient temperature, then heated while being stirred at 320° C. for 20 minutes, and then cooled again to ambient temperature.

Thereafter, the reaction solution was centrifuged at 5500 rpm for 3 minutes by the centrifuge to precipitate the reaction initial stage particles. The precipitated reaction initial stage particles were redispersed with toluene, and the cleaning separation of the reaction initial stage particles was performed by using methanol and ethanol. After that, oleylamine (OLAm) 9.5 mL was added to the reaction initial stage particles, and the reaction initial stage particles were redispersed with the oleylamine (OLAm). As a result, a dispersion (21B) in which the reaction initial stage particles were dispersed in the oleylamine (OLAm) was obtained.

Thereafter, a mixed solution 3.5 mL obtained by mixing the GaCl₃/LAc-OLAm (molar ratio Ga:OLAc=1:1.5, concentration 0.1 M) 3 mL and the S-OLAm/DDT (concentration 0.8 M) 3.5 mL was dropped to the dispersion (21B) from above the dispersion (21B) over 10 minutes while the dispersion (21B) was heated while being stirred at 290° C. After completion of the dropping of the mixed solution, the reaction solution to which the mixed solution had been dropped was heated while being stirred for 110 minutes. Thereafter, the obtained reaction solution (AgGaSe dispersion (21C) containing the AgGaSe-based particles) was cooled to ambient temperature.

Thereafter, trioctylphosphine (TOP) 8 mL was added to the reaction solution (AgGaSe dispersion (21C)), and the mixture was heated and stirred at 150° C. for 5 minutes.

Then, the Se-OLAm/DDT (concentration 0.7 M) 0.34 mL was added to the reaction solution from above the reaction solution, and the mixture was heated at 150° C. for 20 minutes. Subsequently, the Zn(OAc)₂-OLAc/TOP (concentration 0.8 M) 0.3 mL was added to the reaction solution from above the reaction solution, and the mixture was heated at 150° C. for 20 minutes. Subsequently, the Se-OLAm/DDT (Se-OLAm/DDT solution, concentration 0.7 M) 0.17 mL and S-OLAm/DDT (S-OLAm/DDT solution) (concentration 0.8 M) 0.15 mL were added to the reaction solution from above the reaction solution, and the mixture was heated at 150° C. for 20 minutes. Then, Zn(OAc)₂-OLAc/TOP (concentration 0.8 M) 0.3 mL was added to the reaction solution, and the mixture was heated at 150° C. for 20 minutes. Thereafter, the obtained reaction solution (QD dispersion (21D) containing the ZnAgGaSSe-based QD 25) was cooled to ambient temperature.

Thereafter, trioctylphosphine (TOP) 0.4 mL was added to the reaction solution (QD dispersion (21D)) 2 mL. Thereafter, the reaction solution to which the TOP was added was centrifuged at 5500 rpm for 3 minutes by the centrifuge to remove precipitates. Thus, a QD dispersion (21E) containing the QD 25 was obtained. The fluorescence wavelength and the fluorescent half width of the QD 25 in the obtained QD dispersion (21E) were measured by the fluorescence spectrometer described above. The fluorescence quantum yield of the QD 25 in the QD dispersion (21E) was measured by the quantum yield measuring device described above. As shown in FIG. 20, the measurement results indicated optical characteristics including the fluorescence wavelength of 633 nm, the fluorescent half width of 23.9 nm, and the quantum yield of 75%.

Therefore, also in the present example, the QD 25 that emit red light and have the fluorescent half width of 45 nm or less and the fluorescence quantum yield of 35% or more could be obtained. Therefore, also in the present example, it is found that, by using the QD 25 as the QDs, the light-emitting element 1 that contains the Cd-free chalcopyrite-based QDs having the narrow fluorescent half width and the high fluorescence quantum yield and that emits red light can be provided.

Note that the composition of the reaction initial stage particles, the post-added element, the fluorescence wavelength, the fluorescent half width, the fluorescence quantum yield, the S raw material as the S source, and the Se raw material as the Se source in the present example are also collectively shown in Table 3 below.

TABLE 1

| | Initial stage | | | | | |
|---|---|---|---|---|---|---|
| | particles | | Wavelength | Half width | | |
| Example | composition | Post-added element | (nm) | (nm) | PLQY (%) | S raw material |
| 1 | AgGaS | InGaS | 532 | 38 | 45 | TETDS-OLAm, S-ODE |
| 2 | AgGaS | InGaS | 539 | 35.4 | 75 | TETDS-OLAm, S-ODE |
| 3 | AgGaS | InGaS | 526.5 | 34.8 | 54 | DPTT-OLAm, S-ODE |
| 4 | AgGaS | InGaS | 527.5 | 36.9 | 56 | DTDM-OLAm, S-ODE |
| 5 | AgGaS | InGaS | 532 | 36.9 | 65 | IPXDS-OLAm, S-ODE |
| 6 | AgGaS | InGaS | 542 | 36.5 | 71 | TMTDS-OLAm, S-ODE |
| 7 | AgGaS | InGaS | 548.5 | 30.5 | 59 | TETDS-OLAm, S-ODE |
| 8 | AgGaS | InGaS | 546.5 | 36.2 | 81 | TETDS-OLAm, S-ODE |

TABLE 2

| | Initial stage | | | | | | |
|---|---|---|---|---|---|---|---|
| | particles | Post-Added | Wavelength | Half width | PLQY | | |
| Example | composition | element | (nm) | (nm) | (%) | S raw material | Remarks |
| 9 | AgGaS | InGaS | 522 | 38 | 46 | S-ODE | |
| 10 | AgGaS | InGaS | 534 | 40 | 45 | S-ODE | |
| 11 | AgGaS | InGaS | 536.5 | 29.4 | 71 | TETDS-OLAm, S-ODE | |
| 12 | AgGaS | InGaS | 530.5 | 38 | 86 | TETDS-OLAm, S-ODE | After synthesizing initial |
| | | | | | | | stage particles, cleaning |
| | | | | | | | between InS post-addition |
| | | | | | | | and GaS post-addition. |
| 13 | AgGaS | InGaS | 537.5 | 25 | 63 | TETDS-OLAm, S-ODE | Perform centrifugal |
| | | | | | | | separation and cleaning |
| | | | | | | | separation. |
| 14 | AgGaS | InGaS | 531 | 29.3 | 85 | TETDS-OLAm, S-ODE | Amounts of In, Ga, and S |
| | | | | | | | at the time of covering |
| | | | | | | | initial stage particles are |
| | | | | | | | larger than in example 13. |
| 15 | AgGaS | ZnInGaS | 528 | 31 | 84 | TETDS-OLAm, S-ODE, S-TOP | |

TABLE 3

| | Initial stage | | | | | | |
|---|---|---|---|---|---|---|---|
| | particles | Post-added | Wavelength | Half width | PLQY | S raw material solution and Se | |
| | composition | element | (nm) | (nm) | (%) | raw material solution | Remarks |
| Example 16 | AgGaSe | ZnGaSSe | 642 | 33 | 76 | S-OLAm/DDT, Se-OLAm/DDT | |
| Example 17 | AgGaSe | GaSSe | 639 | 30.5 | 56 | S-OLAm/DDT, Se-OLAm/DDT | Post-added element does |
| | | | | | | | not contain Zn, and S raw |
| | | | | | | | material is added at a low |
| | | | | | | | temperature |
| Example 18 | AgGaSe | ZnGaSSe | 633 | 27 | 81 | S-OLAm/DDT, Se-OLAm/DDT | Zn is added to post-added |
| | | | | | | | element in example 17 |
| Example 19 | AgGaSe | ZnGaSSe | 630.5 | 24.5 | 70 | S-OLAm/DDT, Se-OLAm/DDT | Zn raw material used in |
| | | | | | | | example 18 is changed to |
| | | | | | | | Zn-OLAc/OLAm |
| Example 20 | AgInGaSe | ZnGaS | 631 | 25 | 67 | S-OLAm/DDT, Se-OLAm/DDT | In is added to initial stage |
| | | | | | | | particles composition |
| Example 21 | AgGaSe | ZnGaSSe | 633 | 23.9 | 75 | S-OLAm/DDT, Se-OLAm/DDT | Post-added element in |
| | | | | | | | example 18: Ga and Se are |
| | | | | | | | changed to Ga and S |

As shown in Tables 1 to 3, according to examples 1 to 21, favorable light-emission characteristics were obtained in all cases.

Note that “Post-added element” described in Tables 1 to 3 includes the composition of the shell 25b covering the surface of the core 25a. However, as a result of the imaging using the transmission electron microscope (TEM) and the analysis using TEM-EDX by the energy dispersive X-ray (EDX) analyzer, it was found that a clear core-shell structure could not be confirmed and all the added raw materials were mixed crystallized. Note that, in Tables 1 to 3, “initial stage particles composition” and “post-added element” are separately described.

In example 17, the QD 25 do not contain Zn, and in example 18, the QD 25 contain Zn. As can be seen from the comparison between example 17 and example 18, favorable light-emission characteristics were obtained in example 18 than in example 17.

As shown in Tables 1 to 3, according to each of examples 1 to 21, it was found that the fluorescent half width of the QD 25 can be 45 nm or less, preferably 30 nm or less. As shown in Tables 1 to 3, according to examples 1 to 21, it was found that the fluorescence quantum yield can be 35% or more, preferably 70% or more.

As shown in Tables 1 to 3, according to examples 1 to 21, it was found that the fluorescence wavelength can be adjusted within the range from 400 nm to 700 nm, the QD 25 that emits green light can be synthesized in examples 1 to 15, and the QD 25 that emits red light can be synthesized in examples 16 to 21.

On the other hand, in any of the methods for synthesizing AIS-based QDs described in PTLs 1 to 5 and NPLs 1 and 2, it is difficult to synthesize QDs, or even if QDs can be synthesized, only QDs having a low emission intensity can be obtained. In particular, in the methods for synthesizing QDs described in PTLs 1 to 5 and NPLs 1 and 2, even if the QDs can be synthesized, the fluorescent half width is 45 nm or more or the fluorescence quantum yield is 35% or less in the green wavelength region to the red wavelength region, and thus AgInₓGa₁₋ₓS_{y}Se_{1-y}-based or ZnAgInₓGa₁₋ₓS_{y}Se_{1-y}-based quantum dots (0≤x<1, 0≤y≤1) having the narrow fluorescent half width and the high fluorescence quantum yield as in the present examples cannot be obtained.

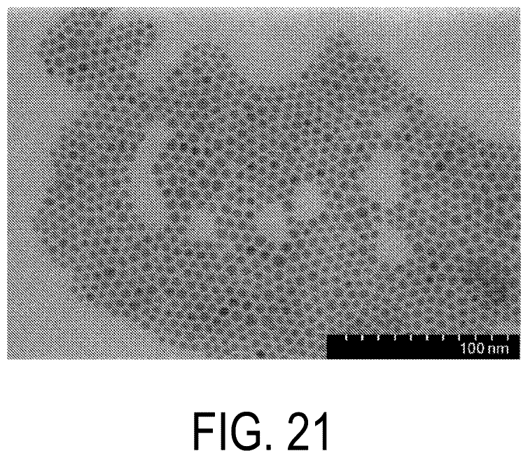

The AgInGaS-based QD 25 in the AgInGaS dispersion (8B) in example 8 was measured using the scanning electron microscope (SEM). FIG. 21 is an image illustrating a scanning electron micrograph of the QD 25 obtained in example 8.

As illustrated in FIG. 21, according to example 8, it was found that a large number of QD 25 can be mass-produced to have a substantially uniform particle size.

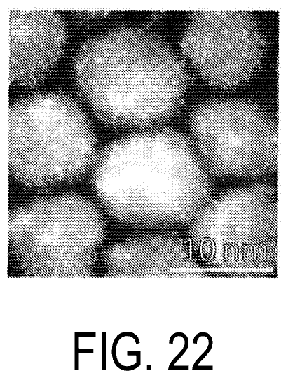

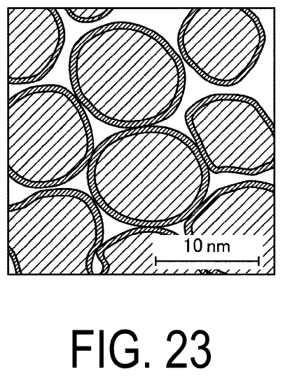

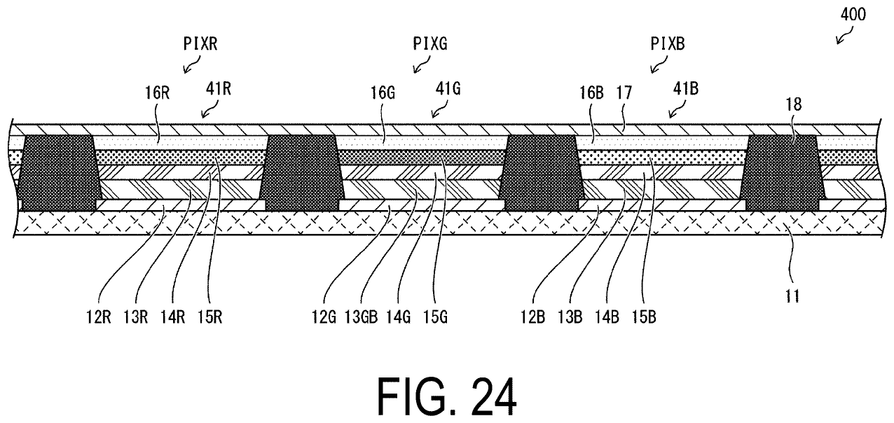

FIG. 22 illustrates an analysis image (observation image) obtained by analyzing the ZnAgGaSSe-based QD 25 in example 16 using TEM-EDX. FIG. 23 is a partial schematic view of the analysis image (observation image) illustrated in FIG. 22. As illustrated in FIGS. 22 and 23, it was found that the more Zn was detected, the darker the color was detected, and Zn was mainly present (unevenly distributed) on the surfaces of the QDs 25.

As described above, according to the present embodiment, for example, QD 25 that exhibit high-luminance green fluorescence or red fluorescence can be stably obtained. By applying the QD 25 to light-emitting devices such as LEDs, backlight devices, and display devices, excellent light-emission characteristics can be obtained in each device.

### Second Embodiment

Another embodiment of the disclosure will be described below. Note that, for convenience of description, members having the same functions as those of the members described in the above-described embodiment will be denoted by the same reference numerals and signs, and the description thereof will not be repeated.

### Application to Display Device

As described above, the light-emitting element 1 is applied as, for example, the light source for the display device. In the present embodiment, as described above, the fluorescence wavelength of the QD 25 and the fluorescence wavelength of the QD layer 15 can be controlled in the range of 400 nm or more and 700 nm or less, but the QD 25 and the QD layer 15 preferably perform the green light emission or the red light emission. Thus, the light-emitting element 1 is preferably applied as, for example, the green light source or the red light source of the display device. The light-emitting element 1 may be a light source which lights up by combining light sources of colors (a red light source, a green light source, and a blue light source) corresponding to pixels (an R pixel, a G pixel, and a B pixel), respectively. The display device utilizing this light source can express an image by a plurality of pixels each including the R pixel, the G pixel, and the B pixel.

FIG. 6 is a cross-sectional view schematically illustrating an overall configuration of main portions of a display device 400 (light-emitting device) according to the present embodiment.

Note that the present embodiment is described based on a case where the light-emitting device according to the present embodiment is the display device. However, as described above, the light-emitting device according to the present embodiment may be an illumination device such as the LED or the backlight device. The light-emitting device may be used as, for example, a display panel or the light source (illumination device) of the display device 400.

As illustrated in FIG. 6, the display device 400 (light-emitting device) according to the present embodiment includes a plurality of pixels each including the R pixel (PIXR), the G pixel (PIXG), and the B pixel (PIXB). Note that the R pixel may be referred to as an R subpixel. This similarly applies to the G pixel and the B pixel.

In the display device 400, the PIXR, PIXG, and PIXB constitute one picture element. In the present embodiment, in a case where the PIXR, PIXG, and PIXB do not particularly need to be distinguished, the PIXR, PIXG, and PIXB are collectively referred to simply as a PIX.

The display device 400 has a structure in which a light-emitting element layer including a plurality of kinds of light-emitting elements having different emission wavelengths is provided.

The light-emitting element layer is provided with the light-emitting element corresponding to each PIX. The PIXR is provided with the light-emitting element 41R as the red light-emitting element. The PIXG is provided with the light-emitting element 41G as the green light-emitting element. The PIXB is provided with the light-emitting element 41B as the blue light-emitting element.

As illustrated in FIG. 6, the light-emitting element 41R includes an anode electrode 12R, an HIL 13R, an HTL 14R, a QD layer 15R, an ETL 16R, and the cathode electrode 17. The light-emitting element 41G includes an anode electrode 12G, an HIL 13G, an HTL 14G, a QD layer 15G, an ETL 16G, and the cathode electrode 17. The light-emitting element 41B includes an anode electrode 12B, an HIL 13B, an HTL 14B, a QD layer 15B, an ETL 16B, and the cathode electrode 17.

Each of the light-emitting elements 41R, 41G, and 41B has a configuration similar to that of the light-emitting element 1 illustrated in FIG. 1. Thus, each of each of the anode electrode 12R, the anode electrode 12G, and the anode electrode 12B has a configuration similar to that of the anode electrode 12 illustrated in FIG. 1. Each of each of the HIL 13R, the HIL 13G, and the HIL 13B has a configuration similar to that of the HIL 13 illustrated in FIG. 1. Each of each of the HTL 14R, the HTL 14G, and the HTL 14B has a configuration similar to that of the HTL 14 illustrated in FIG. 1. Each of each of the QD layer 15R, the QD layer 15G, and the QD layer 15B has a configuration similar to that of the QD layer 15 illustrated in FIG. 1. Each of each of the ETL 16R, the ETL 16G, and the ETL 16B has a configuration similar to that of the ETL 16 illustrated in FIG. 1.

Note that at least one of the red QDs and the green QDs used in the PIXR (light-emitting element 41R) and the PIXG (light-emitting element 41G), respectively, is desirably made of the above-described QD 25, and more desirably, both of the red QDs and the green QDs are made of the above-described QD 25. Note that the blue QDs used in the PIXB (light-emitting element 41B) are not particularly limited. Note that, for example, ZnS may be used as the blue QDs if the blue QDs is limited to a non-Cd-based material.

Each of the PIXR, PIXG, and PIXB is formed by, for example, using an ink-jet or the like for separately patterning layers corresponding to respective layers of the light-emitting element 1 including at least the QD layer 15 on the substrate 11 provided with a bank 18. Note that, as the blue QDs used in the QD layer 15B of the PIXB (light-emitting element 41B), for example, ZnS may be used if the blue QDs is limited to the non-Cd-based material.

Film formation of the ETL 16 may be implemented with a plurality of pixel units or may be implemented in common for the plurality of pixels, provided that the display device 400 can light up the PIXR, PIXG, and PIXB individually.

The disclosure is not limited to the embodiments described above, and various modifications may be made within the scope of the claims. Embodiments obtained by appropriately combining technical approaches disclosed in the different embodiments also fall within the technical scope of the disclosure. Moreover, novel technical features may be formed by combining the technical approaches stated in each of the embodiments.

### REFERENCE SIGNS LIST

1. 41B, 41G, 41R Light-emitting element (electroluminescent element)
12, 12B, 12G, 12R Anode electrode
13, 13B, 13G, 13R HIL (hole injection layer)
14, 14B, 14G, 14R HTL (hole transport layer)
15, 15B, 15G, 15R QD layer
16, 16B, 16G, 16R ETL (electron transport layer)
17 Cathode electrode
21 Ligand
25 QD (quantum dot)
25a Core
25b Shell
400 Display device (light-emitting device)

1. An electroluminescent element comprising:
an anode electrode;
a cathode electrode; and
a quantum dot light-emitting layer provided between the anode electrode and the cathode electrode, the quantum dot light-emitting layer containing quantum dots,
wherein the quantum dots are AgInₓGa₁₋ₓS_{y}Se_{1-y}-based or ZnAgInₓGa₁₋ₓS_{y}Se_{1-y}-based Cd-free quantum dots (0≤x<1, 0≤y≤1), and exhibit fluorescence characteristics having a fluorescent half width of 45 nm or less and a fluorescence quantum yield of 35% or more in a green wavelength region to a red wavelength region.

2. The electroluminescent element according to claim 1,
wherein each of the quantum dots contains at least Ag, Ga, and at least one of S and Se.

3. The electroluminescent element according to claim 2,
wherein each of the quantum dots has a core-shell structure including a core of a nanocrystal including at least Ag, Ga, and at least one of S and Se and a shell.

4. The electroluminescent element according to claim 1,
wherein the fluorescent half width of each of the quantum dots is 35 nm or less.

5. The electroluminescent element according to claim 1,
wherein the quantum dots exhibit fluorescence characteristics having the fluorescence quantum yield of 70% or more.

6. The electroluminescent element according to claim 1,
wherein a fluorescence wavelength of each of the quantum dots is within a range of 400 nm or more and 700 nm or less.

7. The electroluminescent element according to claim 1,
wherein each of the quantum dots has a fluorescent half width of 30 nm or less, a fluorescence quantum yield of 80% or more, and a fluorescence wavelength within a range of 510 nm or more and 650 nm or less.

8. The electroluminescent element according to claim 1,
wherein the quantum dots include at least one structure selected from structures represented by the following formula (1):
—S—C(═S)—NR¹R² (1)
(where each of R¹ and R² independently represents —(CH₂)ₙ—CH₃ group, —CH₃ group, or benzyl group, and n represents an integer from 1 to 3,)
and the following formula (2):
—S—R³ (2)
(where R 3 represents
a phenyl group, a benzyl group, or a pyridyl group).

9. The electroluminescent element according to claim 1,
wherein a layer thickness of the quantum dot light-emitting layer is within a range of 2 nm or more and 20 nm or less.

10. The electroluminescent element according to claim 1,
wherein a hole injection layer and a hole transport layer are provided, in this order from the anode electrode side, between the anode electrode and the quantum dot light-emitting layer,
an electron transport layer is provided between the cathode electrode and the quantum dot light-emitting layer,
the hole injection layer includes a composite of poly(3,4-ethylenedioxythiophene) and polystyrene sulfonic acid,
the hole transport layer includes poly(N-vinylcarbazole), and
the electron transport layer includes ZnMgO.

11. The electroluminescent element according to claim 1,
wherein the quantum dots are ZnAgInₓGa₁₋ₓS_{y}Se_{1-y}-based quantum dots (0≤x<1, 0≤y≤1), and Zn is unevenly distributed mainly on surfaces of the quantum dots.

12. A light-emitting device comprising:
at least one electroluminescent element according to claim 1.

13. The light-emitting device according to claim 12,
wherein the light-emitting device is a display device.
